(19) United States
(12) Patent Application Publication
(10) Pub. No.: US 2019/0265593 A1
(43) Pub. Date: Aug. 29, 2019

(54) SILICON-CONTAINING RESIST UNDERLAYER FILM-FORMING COMPOSITION CONTAINING ORGANIC GROUP HAVING DIHYDROXY GROUP

(71) Applicant: NISSAN CHEMICAL CORPORATION, Tokyo (JP)

(72) Inventors: Wataru SHIBAYAMA, Toyama-shi (JP); Makoto NAKAJIMA, Toyama-shi (JP); Ken ISHIBASHI, Toyama-shi (JP); Rikimaru SAKAMOTO, Toyama-shi (JP)

(73) Assignee: NISSAN CHEMICAL CORPORATION, Tokyo (JP)

(21) Appl. No.: 16/345,821

(22) PCT Filed: Oct. 25, 2017
(86) PCT No.: PCT/JP2017/038505

§ 371 Date: Apr. 29, 2019

(30) Foreign Application Priority Data
Oct. 27, 2016 (JP) 2016-210966

(51) Int. Cl. G03F 7/11; H01L 21/027; G03F 7/42; G03F 7/20; G03F 7/075

(52) U.S. Cl. CPC G03F 7/11; H01L 21/0274; C08L 63/00; G03F 7/2002; G03F 7/0752; G03F 7/423

(57) ABSTRACT

There is provided a silicon-containing resist underlayer film that is usable as a hard mask in a lithography process and can be removed by a wet process using a chemical solution, and particularly, a mixed aqueous solution of sulfuric acid with hydrogen peroxide (SPM).

A resist underlayer film-forming composition is represented by comprising a hydrolysis-condensation of a hydrolysable silane having an epoxy group in an amount of 10 to 90% by mole relative to the total amount of hydrolysable silanes by an aqueous solution of an alkaline substance, and
in a reaction system containing the hydrolysis-condensate, a hydrolysis-condensate containing an organic group having a dihydroxy group obtained by ring-opening the epoxy group by an inorganic acid or a cation exchange resin is further comprised.

A resist underlayer film is obtained by applying the resist underlayer film-forming composition to a substrate and baking the composition, the resist underlayer film being capable of being removed by an aqueous solution containing sulfuric acid and hydrogen peroxide at a mass ratio of H₂SO₄:H₂O₂ of 1:1 to 4:1.

### TECHNICAL FIELD

The present invention relates to a composition for forming an underlayer film between a substrate and a resist (e.g., a photoresist and an electron beam resist) used in production of a semiconductor device. Specifically, the present invention relates to a resist underlayer film-forming composition for lithography for forming an underlayer film to be used as an underlayer of a photoresist in a lithography process for production of a semiconductor device. The present invention relates to a method for forming a resist pattern using the underlayer film-forming composition.

### BACKGROUND ART

In production of a semiconductor device, microprocessing has been conventionally carried out through lithography using a photoresist. The microprocessing is a processing method in which a thin film is formed from a photoresist on a semiconductor substrate such as a silicon wafer, irradiated with active light such as ultraviolet light through a mask pattern including a pattern of the semiconductor device, and developed to obtain a photoresist pattern, and the substrate is etched using the obtained photoresist pattern as a protective film to form fine concaves and convexes corresponding to the pattern on a surface of the substrate. In recent years, an increase in degree of integration of semiconductor devices has advanced. As active light, an ArF excimer laser (193 nm) is used instead of a KrF excimer laser (248 nm), and the wavelength of active light tends to be decreased. This tendency affects reflection of active light on a semiconductor substrate, which is a severe problem.

As an underlayer film provided between a semiconductor substrate and a photoresist, a film known as a hard mask containing a metallic element such as silicon and titanium is used. In this case, components of the photoresist are largely different from those of the hard mask, and thus rates of removing the photoresist and the hard mask by dry etching largely depend on the type of gas used in the dry etching. Appropriate selection of the gas type allows the hard mask to be removed by dry etching without largely reducing the film thickness of the photoresist. In order to achieve various effects including an anti-reflective effect, a resist underlayer film has been arranged between the semiconductor substrate and the photoresist in recent production of a semiconductor device. While a composition for the resist underlayer film has been investigated, development of a novel material for the resist underlayer film is desired due to a variety of required properties.

In recent years, a three-layer process has been used due to a finer implant layer of a most advanced semiconductor device. However, a general three-layer process may damage a substrate during dry etching. Therefore, a step of removing a silicon-containing resist underlayer film by a wet process is desired.

A resist underlayer film-forming composition obtained by adding acetic acid to a polysiloxane obtained by hydrolysis-condensation of 3,4-epoxycyclohexylethyltrimethoxysilane and phenyltrimethoxysilane in the presence of alkaline catalyst has been disclosed (Examples in Patent Document 1).

A resist underlayer film-forming composition obtained from a polysiloxane produced by mixing tetramethoxysilane, phenyltrimethoxysilane, and 2-(3,4-epoxycyclohexyl)ethyltrimethoxysilane in an ethanol containing a methanesulfonic acid aqueous solution, followed by hydrolysis-condensation has been disclosed (Examples in Patent Document 2).

### PRIOR ART DOCUMENTS

### Patent Documents

Patent Document 1: Japanese Patent Application Publication No. 2007-163846 (JP 2007-163846 A)

Patent Document 2: Japanese Patent Application Publication No. 2012-078602 (JP 2012-078602 A)

### SUMMARY OF THE INVENTION

### Problem to be Solved by the Invention

An object of the present invention is to provide a resist underlayer film-forming composition for lithography usable in production of a semiconductor device, and specifically, to provide a resist underlayer film-forming composition for lithography for forming a resist underlayer film usable as a hard mask. Another object of the present invention is to provide a resist underlayer film-forming composition for lithography for forming a resist underlayer film usable as an anti-reflective coating. Yet another object of the present invention is to provide a resist underlayer film for lithography that does not cause intermixing with a resist and has a higher dry etching rate than that of the resist and a resist underlayer film-forming composition for forming the underlayer film.

The present invention provides a resist underlayer film-forming composition for forming a resist under layer film on which an excellent resist pattern profile can be formed by exposing a resist as an upper layer and developing the resist by an alkaline developer or an organic solvent and to which a rectangular resist pattern can be transferred by later dry etching.

In the general three-layer process, a substrate may be damaged by dry etching, and thus a step of removing a silicon-containing resist underlayer film by a wet process is desired. Accordingly, the present invention provides a silicon-containing resist underlayer film capable of being removed by a wet process using a chemical solution, and particularly by a mixed aqueous solution of sulfuric acid with hydrogen peroxide (SPM).

### Means for Solving the Problems

A first aspect of the present invention is a resist underlayer film-forming composition comprising a hydrolysis-condensate containing an organic group having a dihydroxy group, wherein the dihydroxy group in the hydrolysis-condensate containing an organic group having a dihydroxy group is produced by a ring opening reaction of an epoxy group in a hydrolysis-condensate containing an organic group having the epoxy group by an inorganic acid or a cation exchange resin, and the hydrolysis-condensate containing an organic group having an epoxy group is produced by hydrolysis-condensation of a hydrolysable silane having an epoxy group in an amount of 10 to 90% by mole relative to the total amount of hydrolysable silanes by an aqueous solution of an alkaline substance.

A second aspect of the present invention is the resist underlayer film-forming composition according to the first aspect, wherein the hydrolysable silane having an epoxy group in an amount of 10 to 90% by mole relative to the total amount of hydrolysable silanes contains a hydrolysable silane of Formula (1):

R¹ₐR²_{b}Si(R³)_{4-(a+b)} Formula (1)

(wherein R¹ is a cyclohexylepoxy group, a glycidoxyalkyl group, or an organic group containing a cyclohexylepoxy group and a glycidoxyalkyl group and bonded to a silicon atom through a Si—C bond, R² is an alkyl group, an aryl group, a halogenated alkyl group, a halogenated aryl group, an alkoxyaryl group, an alkenyl group, an acyloxyalkyl group, an organic group having an acryloyl group, a methacryloyl group, a mercapto group, an amino group, an amide group, a hydroxyl group, an alkoxy group, an ester group, a sulfonyl group, or a cyano group, or a combination thereof and bonded to a silicon atom through a Si—C bond, R³ is an alkoxy group, an acyloxy group, or a halogen group, a is an integer of 1, b is an integer of 0 to 2, and a+b is an integer of 1 to 3).

A third aspect of the present invention is the resist underlayer film-forming composition according to the second aspect, wherein the hydrolysable silane having an epoxy group in an amount of 10 to 90% by mole relative to the total amount of hydrolysable silanes contains the hydrolysable silane of Formula (1), and at least one selected from the group consisting of hydrolysable silanes of Formula (2):

R⁴_{c}Si(R⁵)_{4-c} Formula (2)

(wherein R⁴ is an alkyl group, an aryl group, a halogenated alkyl group, a halogenated aryl group, an alkoxyaryl group, an alkenyl group, an acyloxyalkyl group, an organic group having an acryloyl group, a methacryloyl group, a mercapto group, an amino group, an amide group, a hydroxyl group, an alkoxy group, an ester group, a sulfonyl group, or a cyano group, or a combination thereof and bonded to a silicon atom through a Si—C bond, R⁵ is an alkoxy group, an acyloxy group, or a halogen group, and c is an integer of 0 to 3), and Formula (3):

[R⁶_{d}Si(R⁷)_{3-d}]₂Yₑ Formula (3)

(wherein R⁶ is an alkyl group bonded to a silicon atom through an Si—C bond, R⁷ is an alkoxy group, an acyloxy group, or a halogen group, Y is an alkylene group or an arylene group, d is an integer of 0 or 1, and e is an integer of 0 or 1).

A fourth aspect of the present invention is the resist underlayer film-forming composition according to the second or third aspect, wherein the hydrolysable silane of Formula (1) is contained in an amount of 10 to 90% by mole relative to the total amount of hydrolysable silanes.

A fifth aspect of the present invention is the resist underlayer film-forming composition according to any one of the first to fourth aspects, further comprising a crosslinkable compound.

A sixth aspect of the present invention is the resist underlayer film-forming composition according to any one of the first to fifth aspects, further comprising an acid or an acid generator.

A seventh aspect of the present invention is the resist underlayer film-forming composition according to any one of the first to sixth aspects, further comprising water.

An eighth aspect of the present invention is the resist underlayer film-forming composition according to any one of the first to seventh aspects, wherein the production of hydrolysis-condensate by hydrolysis-condensation of the hydrolysable silane by the aqueous solution of an alkaline substance and the ring opening reaction of the epoxy group by the inorganic acid or the cation exchange resin occur in an organic solvent.

A ninth aspect of the present invention is a resist underlayer film obtained by applying the resist underlayer film-forming composition according to any one of the first to eighth aspects to a substrate and baking the composition, the resist underlayer film being capable of being removed by an aqueous solution containing sulfuric acid and hydrogen peroxide at a mass ratio of H₂SO₄:H₂O₂ of 1:1 to 4:1.

A tenth aspect of the present invention is a method for producing the resist underlayer film-forming composition according to any one of claims 1 to 8, characterized by comprising steps of: producing a hydrolysis-condensate containing an organic group having an epoxy group by hydrolysis-condensation of a hydrolysable silane having an epoxy group in an amount of 10 to 90% by mole relative to the total amount of hydrolysable silanes by an aqueous solution of an alkaline substance; and ring-opening the epoxy group in a reaction system containing the hydrolysis-condensate containing an organic group having the epoxy group by an inorganic acid or a cation exchange resin to obtain a hydrolysis-condensate containing an organic group having a dihydroxy group.

An eleventh aspect of the present invention is a method for producing a semiconductor device comprising steps of: applying the resist underlayer film-forming composition according to any one of the first to eighth aspects to a semiconductor substrate and baking the composition, to form a resist underlayer film; applying a composition for a resist to the resist underlayer film to form a resist film; exposing the resist film; after exposure, developing the resist to obtain a resist pattern; etching the resist underlayer film through the resist pattern; and processing the semiconductor substrate through the patterned resist and resist underlayer film.

A twelfth aspect of the present invention is a method for producing a semiconductor device comprising steps of: forming an organic underlayer film on a semiconductor substrate; applying the resist underlayer film-forming composition according to any one of the first to eighth aspects to the organic underlayer film and baking the composition, to form a resist underlayer film; applying a composition for a resist to the resist underlayer film to form a resist layer; exposing the resist layer; after exposure, developing the resist to obtain a resist pattern; etching the resist underlayer film through the resist pattern; etching the organic underlayer film through the patterned resist underlayer film; and processing the semiconductor substrate through the patterned organic underlayer film.

A thirteenth aspect of the present invention is the method for producing a semiconductor device according to the eleventh or twelfth aspect, further comprising a step of removing the patterned resist underlayer film by an aqueous solution containing sulfuric acid and hydrogen peroxide.

### Effects of the Invention

In the present invention, the resist underlayer film-forming composition contains the hydrolysis-condensate (polysiloxane) containing an organic group having a dihydroxy group that is obtained by a ring opening reaction of an epoxy group.

The dihydroxy group is formed by a ring opening reaction of an epoxy group. However, in a reaction of an epoxy group with an organic acid, an addition reaction of an organic acid residue occurs during the ring opening reaction of an epoxy group, and thus a dihydroxy structure cannot be formed. When an acid is used in hydrolysis of a hydrolysable silane, ring opening of an epoxy group occurs at the same time as the hydrolysis. As a result, a side reaction of a silanol group with a dihydroxy group also occurs.

In the present invention, the organic solvent contains the aqueous solution of an alkaline substance during hydrolysis of a hydrolysable silane, a silanol group is preferentially formed, and a polysiloxane is formed. After then, an inorganic acid is added to convert an epoxy group to a dihydroxy group. As a result, a resist underlayer film-forming composition containing a polysiloxane containing an organic group having a dihydroxy group is obtained.

In a cohydrolysis-condensate obtained by cohydrolysis-condensation of a tetrafunctional silane such as tetraethoxysilane with a trifunctional silane having an organic group, a crosslinking structure is formed between silanol groups, and thus a resist underlayer film is not intermixed with a resist composition that is applied to the resist underlayer film. However, after the underlayer film and a substrate are processed, such a resist underlayer film cannot be removed by a chemical solution such as a mixed aqueous solution of sulfuric acid with hydrogen peroxide (SPM).

In the present invention, a dihydroxy group obtained by ring opening of an epoxy group forms a crosslinking structure with another dihydroxy group, a silanol group, or an organic crosslinkable compound, and thus a resist underlayer film of the present invention is not intermixed with a resist composition that is applied to the resist underlayer film. After the resist underlayer film is processed, the resist underlayer film can be removed by a mixed aqueous solution of sulfuric acid with hydrogen peroxide (SPM).

The resist underlayer film of the present invention has a unit structure of siloxane containing an organic group having a dihydroxy group. A crosslinking structure based on this unit structure can be removed by a wet process using a chemical solution, and particularly a mixed aqueous solution of sulfuric acid with hydrogen peroxide (SPM). During removal of the resist underlayer film from a substrate, a damage against the substrate can be reduced.

### MODES FOR CARRYING OUT THE INVENTION

The present invention is a resist underlayer film-forming composition comprising a hydrolysis-condensate containing an organic group having a dihydroxy group, wherein the dihydroxy group in the hydrolysis-condensate containing an organic group having a dihydroxy group is produced by a ring opening reaction of an epoxy group in a hydrolysis-condensate containing an organic group having an epoxy group by an inorganic acid or a cation exchange resin, and the hydrolysis-condensate containing an organic group having an epoxy group is produced by hydrolysis-condensation of a hydrolysable silane having an epoxy group in an amount of 10 to 90% by mole relative to the total amount of hydrolysable silanes by an aqueous solution of an alkaline substance.

When the amount of the hydrolysable silane having an epoxy group is less than 10% by mole relative to the total amount of hydrolysable silanes, sufficient resistance to intermixing with a resist composition for coating cannot be secured. Intermixing means that during applying an upper-layer composition to an underlayer film, the underlayer film is dissolved and mixed with the upper-layer composition, which is an undesired phenomenon.

When the amount of the hydrolysable silane having an epoxy group is more than 90% by mole relative to the total amount of hydrolysable silanes, optical property and dry etching resistance cannot be sufficiently secured.

The present invention is a method for producing a resist underlayer film-forming composition characterized by comprising steps of: producing a hydrolysis-condensate containing an organic group having an epoxy group by hydrolysis-condensation of a hydrolysable silane having an epoxy group in an amount of 10 to 90% by mole relative to the total amount of hydrolysable silanes by an aqueous solution of an alkaline substance; and ring-opening the epoxy group in a reaction system containing the hydrolysis-condensate containing an organic group having an epoxy group by an inorganic acid or a cation exchange resin, to obtain a hydrolysis-condensate containing an organic group having a dihydroxy group.

The hydrolysis-condensation of a hydrolysable silane by an aqueous solution of an alkaline substance and the ring opening reaction of an epoxy group in the hydrolysis-condensate by an inorganic acid or a cation exchange resin can occur in an organic solvent. The reaction system containing the hydrolysis-condensate means that in a reaction system where hydrolysis and condensation of silane occur, a ring opening reaction of an epoxy group subsequnently occurs.

The resist underlayer film-forming composition of the present invention contains the hydrolysis-condensate and a solvent. The composition may further contain, as optional components, an acid, water, an alcohol, a curing catalyst, an acid generator, an additional organic polymer, a light-absorbing compound, a surfactant, and the like.

The solid content in the resist underlayer film-forming composition of the present invention is, for example, 0.1 to 50% by mass, 0.1 to 30% by mass, or 0.1 to 25% by mass. Here, the solid content is the content of all components of the resist underlayer film-forming composition except the solvent component.

The ratio of the hydrolysable silane, a hydrolysate thereof, and a hydrolysis-condensate thereof in the solid content is 20% by mass or more, for example, 50 to 100% by mass, 60 to 99% by mass, or 70 to 99% by mass.

As the aforementioned hydrolysis-condensate, a mixture of the hydrolysis-condensate with a partial hydrolysate, in which hydrolysis is not completed during formation of the hydrolysable silane, the hydrolysate, and the hydrolysis-condensate, may be used. The condensate is a polymer having a polysiloxane structure.

As the aforementioned hydrolysable silane, a hydrolysable silane of Formula (1) may be used.

In Formula (1), R¹ is a cyclohexylepoxy group, a glycidoxyalkyl group, or an organic group containing a cyclohexylepoxy group and a glycidoxyalkyl group and bonded to a silicon atom through a Si—C bond. In Formula (1), R¹ is a cyclohexylepoxy group, a glycidoxyalkyl group, or an organic group containing a cyclohexylepoxy group and a glycidoxyalkyl group and bonded to a silicon atom through a Si—C bond. R² is an alkyl group, an aryl group, a halogenated alkyl group, a halogenated aryl group, an alkoxyaryl group, an alkenyl group, an acyloxyalkyl group, an organic group having an acryloyl group, a methacryloyl group, a mercapto group, an amino group, an amide group, a hydroxyl group, an alkoxy group, an ester group, a sulfonyl group, or a cyano group, or a combination thereof and bonded to a silicon atom through a Si—C bond, R³ is an alkoxy group, an acyloxy group, or a halogen group. a is an integer of 1, b is an integer of 0 to 2, and a+b is an integer of 1 to 3.

The alkyl group is a linear or branched alkyl group having a carbon atom number of 1 to 10, and examples thereof include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

A cyclic alkyl group may also be used. Examples of a cyclic alkyl group having a carbon atom number of 1 to 10 include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group. A bicyclo group may also be used.

The alkenyl group is a C₂₋₁₀ alkenyl group, and examples thereof include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butyl ethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butyl ethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

Examples of the aryl group include C₆₋₄₀ aryl groups such as phenyl group, o-methylphenyl group, m-methylphenyl group, p-methylphenyl group, o-chlorophenyl group, m-chlorophenyl group, p-chlorophenyl group, o-fluorophenyl group, p-mercaptophenyl group, o-methoxyphenyl group, p-methoxyphenyl group, p-aminophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group, and 9-phenanthryl group.

The acyloxyalkyl group is a combination of the aforementioned acyloxy group and alkyl group. Examples thereof include acetoxymethyl group, acetoxyethyl group, and acetoxypropyl group.

Examples of the organic group having an epoxy group include glycidoxymethyl, glycidoxyethyl, glycidoxypropyl, glycidoxybutyl, and epoxycyclohexyl.

Examples of the organic group having an acryloyl group include acryloylmethyl, acryloyl ethyl, and acryloylpropyl.

Examples of the organic group having a methacryloyl group include methacryloylmethyl, methacryloylethyl, and methacryloylpropyl.

Examples of the organic group having a mercapto group include ethylmercapto, butylmercapto, hexylmercapto, and octylmercapto.

Examples of the organic group having an amino group include amino group, aminomethyl group, and aminoethyl group.

Examples of the organic group having a cyano group include cyanoethyl and cyanopropyl.

Examples of the organic group having an amino or amide group include cyanuric acid derivatives.

Examples of the organic group having a hydroxyl group include hydroxyphenyl group bonded to an aryl group.

Examples of the organic group having a sulfonyl group include sulfonylalkyl groups and sulfonylaryl groups.

The alkoxyalkyl group is an alkyl group substituted with an alkoxy group. Examples thereof include methoxymethyl group, ethoxymethyl group, ethoxyethyl group, and ethoxymethyl group.

The C₁₋₂₀ alkoxy group is an alkoxy group having a linear, branched, or cyclic alkyl moiety having a carbon atom number of 1 to 20. Examples thereof include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, 1-ethyl-2-methyl-n-propoxy group, and cyclic alkoxy groups such as cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

Examples of the C₂₋₂₀ acyloxy group include methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

Examples of the halogen group include fluorine, chlorine, bromine, and iodine.

Examples of the hydrolysable silane of Formula (1) include as follows.

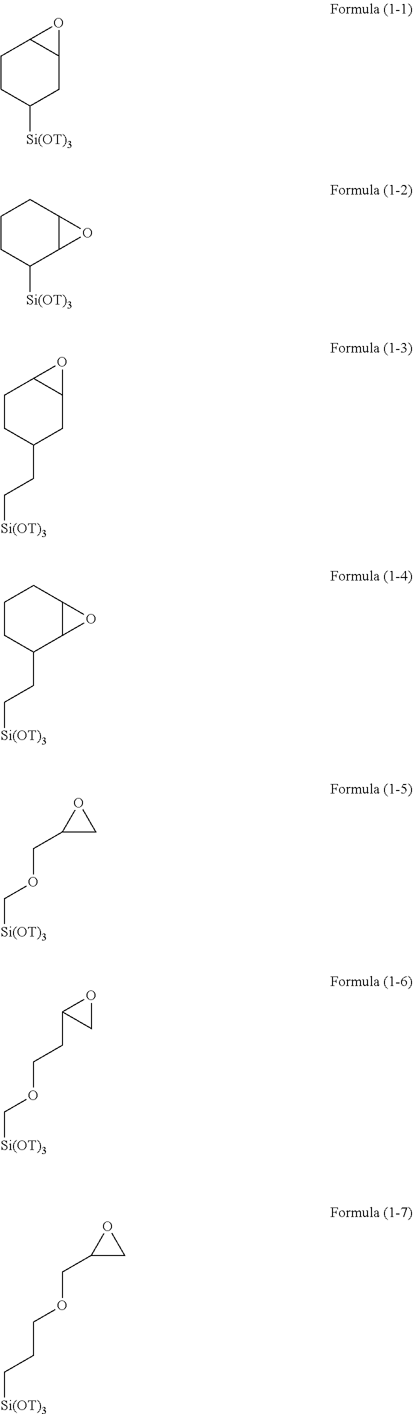

In Formulae described above, T is an alkyl group. Examples of the alkyl group include those exemplified above. The alkyl group is preferably methyl group or ethyl group.

As the hydrolysable silane in the present invention, the hydrolysable silane of Formula (1) and another hydrolysable silane may be used in combination. As the other hydrolysable silane, at least one selected from the group consisting of hydrolysable silanes of Formulae (2) and (3) may be used.

When the hydrolysable silane of Formula (1) and the other hydrolysable silane are used in combination, the hydrolysable silane of Formula (1) can be contained in an amount of 10 to 90% by mole, 15 to 85% by mole, 20 to 80% by mole, or 20 to 60% by mole, relative to the total amount of hydrolysable silanes.

In Formula (2), R⁴ is an alkyl group, an aryl group, a halogenated alkyl group, a halogenated aryl group, an alkoxyaryl group, an alkenyl group, an acyloxyalkyl group, an organic group having an acryloyl group, a methacryloyl group, a mercapto group, an amino group, an amide group, a hydroxyl group, an alkoxy group, an ester group, a sulfonyl group, or a cyano group, or a combination thereof and bonded to a silicon atom through a Si—C bond, R⁵ is an alkoxy group, an acyloxy group, or a halogen group, and c is an integer of 0 to 3.

In Formula (3), R⁶ is an alkyl group bonded to a silicon atom through an Si—C bond, R⁷ is an alkoxy group, an acyloxy group, or a halogen group, Y is an alkylene group or an arylene group, d is an integer of 0 or 1, and e is an integer of 0 or 1.

Examples of the alkyl group, aryl group, halogenated alkyl group, halogenated aryl group, alkoxyaryl group, alkenyl group, acyloxyalkyl group, organic group having an acryloyl group, a methacryloyl group, a mercapto group, an amino group, an amide group, a hydroxyl group, an alkoxy group, an ester group, a sulfonyl group, or a cyano group, alkoxy group, acyloxy group, and halogen group include those exemplified above.

Specific examples of the hydrolysable silane of Formula (2) include tetramethoxysilane, tetrachlorosilane, tetraacetoxysilane, tetraethoxysilane, tetra-n-propoxysilane, tetraisopropoxysilane, tetra-n-butoxysilane, tetraacetoxysilane, methyltrimethoxysilane, methyltrichlorosilane, methyltriacetoxysilane, methyltripropoxysilane, methyltriacetoxysilane, methyltributoxysilane, methyltripropoxysilane, methyltriamiloxysilane, methyltriphenoxysilane, methyltribenzyloxysilane, methyltriphenethyloxysilane, ethyltrimethoxysilane, ethyltriethoxysilane, vinyltrimethoxysilane, vinyltrichlorosilane, vinyltriacetoxysilane, vinyltriethoxysilane, vinyltriacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, isopropoxyphenyltrimethoxysilane, isopropoxyphenyltriethoxysilane, isopropoxyphenyltriacetoxysilane, isopropoxyphenyltrichlorosilane, isopropoxybenzyltrimethoxysilane, isopropoxybenzyltriethoxysilane, isopropoxybenzyltriacetoxysilane, isopropoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptoproyltriethoxysilane, β-cyanoethyltriethoxysilane, chloromethyltrimethoxysilane, chloromethyltriethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiethoxysilane, methylvinyldimethoxysilane, methylvinyldiethoxysilane, acetoxymethyltrimethoxysilane, acetoxyethyltrimethoxysilane, acetoxypropyltrimethoxysilane, acetoxymethyltriethoxysilane, acetoxyethyltriethoxysilane, and acetoxypropyltriethoxysilane.

Specific examples of the hydrolysable silane of Formula (3) include methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butyl enebi strimethoxysil ane, phenyl enebi strimethoxysilane, phenylenebistriethoxysilane, phenyl enebismethyl diethoxysilane, phenylenebismethyldimethoxysilane, naphthylenebistrimethoxysilane, bistrimethoxydisilane, bistriethoxydisilane, bisethyldiethoxydisilane, and bismethyldimethoxydisilane.

Examples of the silane of Formula (2) include the following silanes.

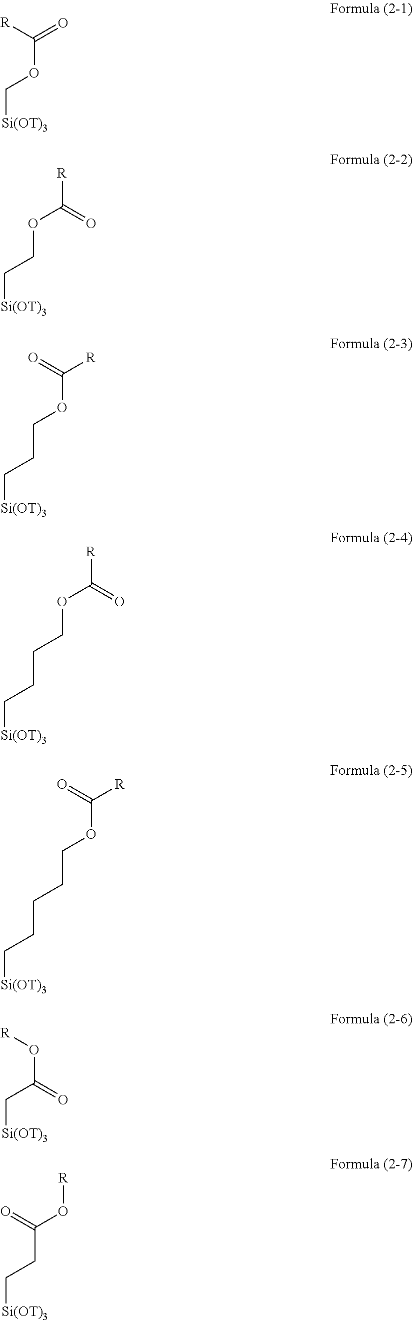

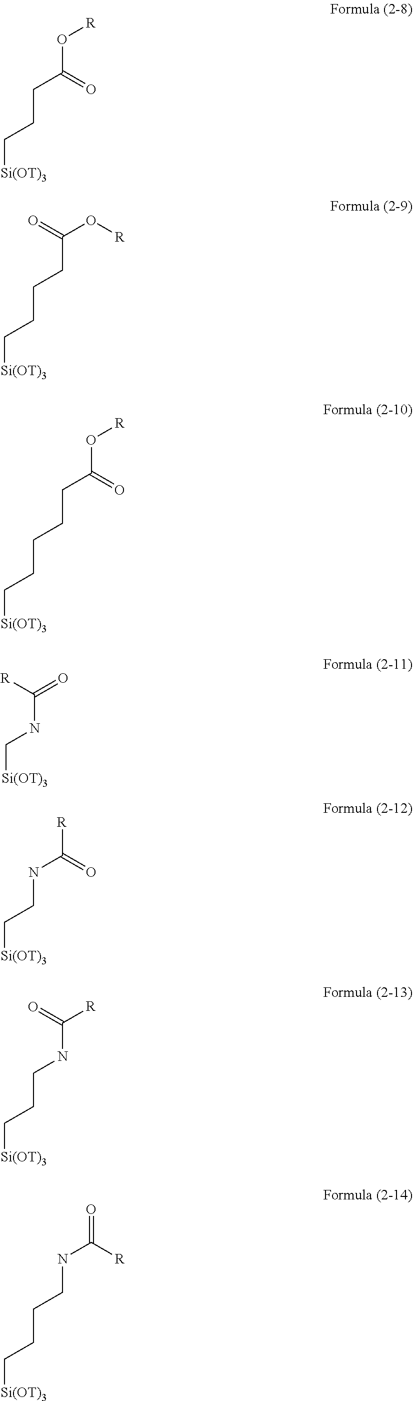

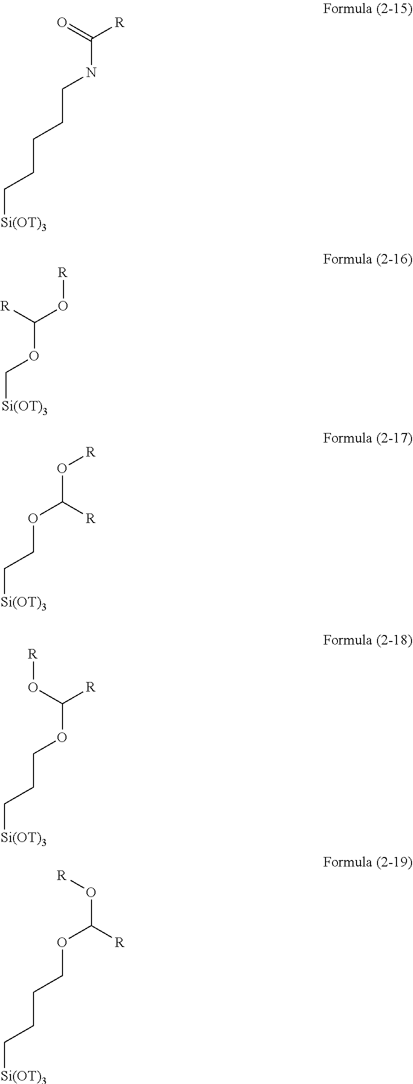

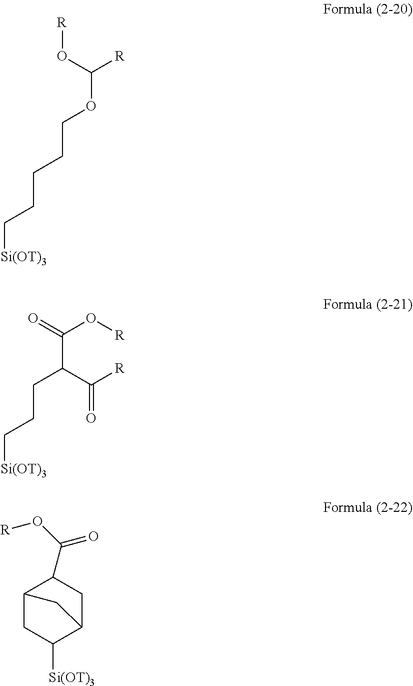

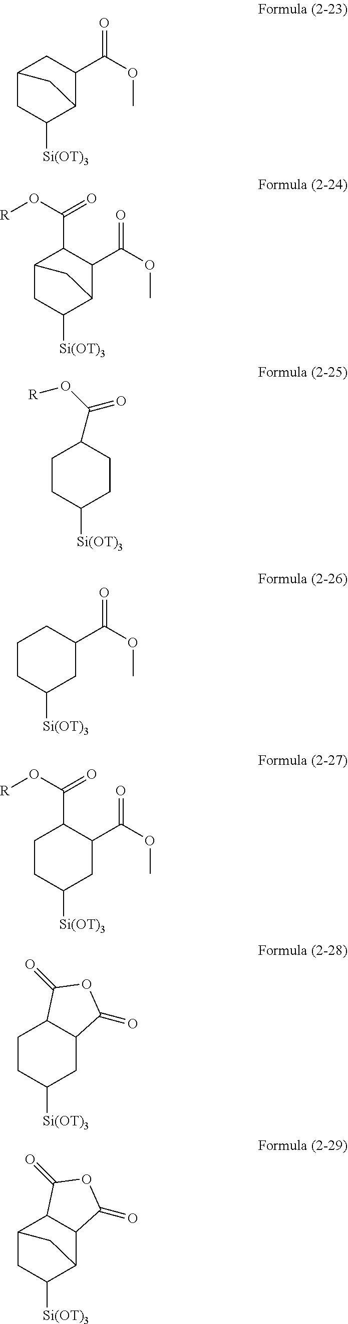

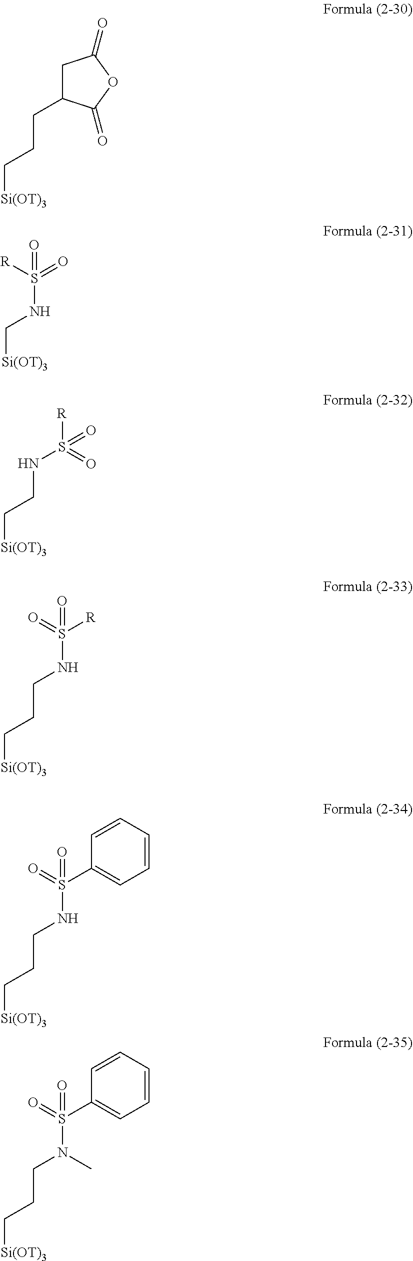

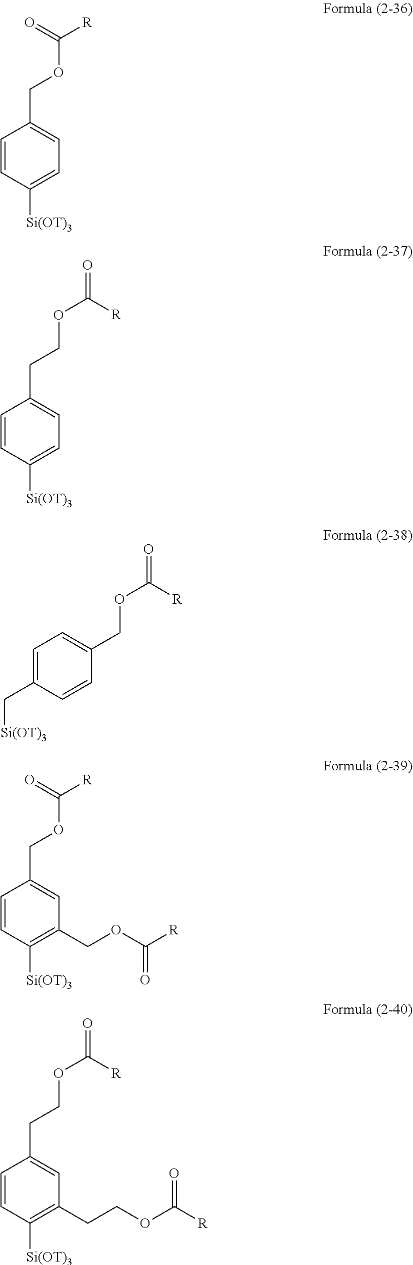

In Formulae described above, T is an alkyl group. Examples of the alkyl group include those exemplified above. The alkyl group is preferably methyl group or ethyl group.

In Formulae described above, R are exemplified as follows.

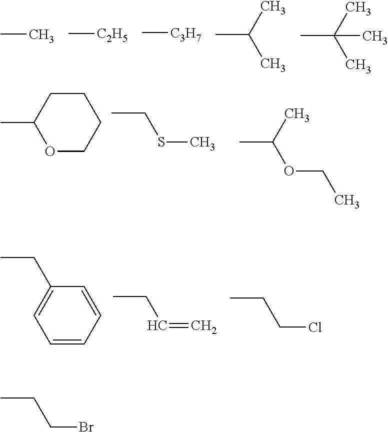

By hydrolysis of an acyloxy group, a blocked hydroxyl group, or an alkoxyalkoxyalkyl group in Formulae described above by an inorganic acid, a carboxylic acid or a hydroxyl group can be produced.

Examples of the hydrolysis-condensate used in the present invention include as follows.

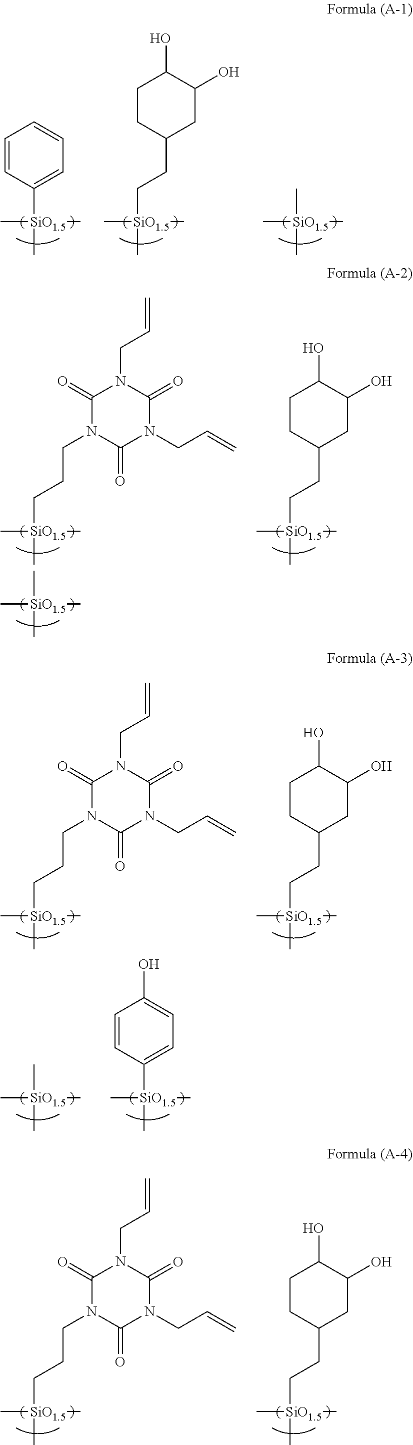

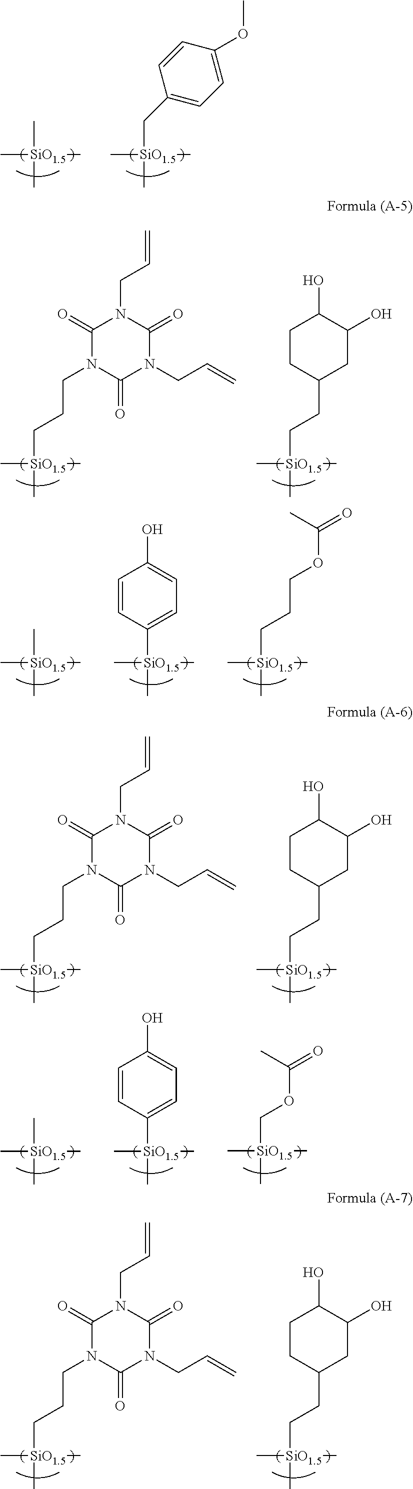

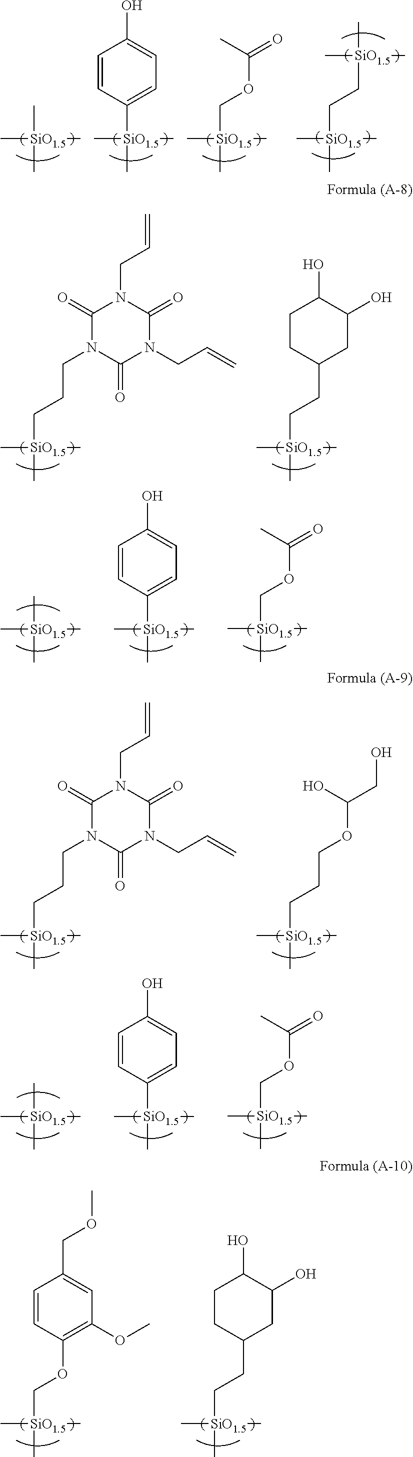

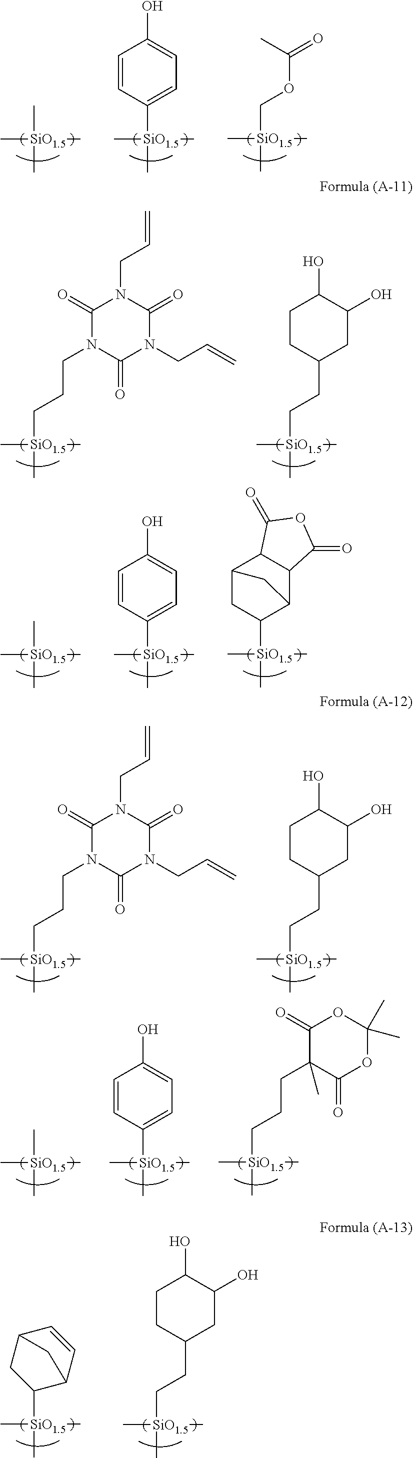

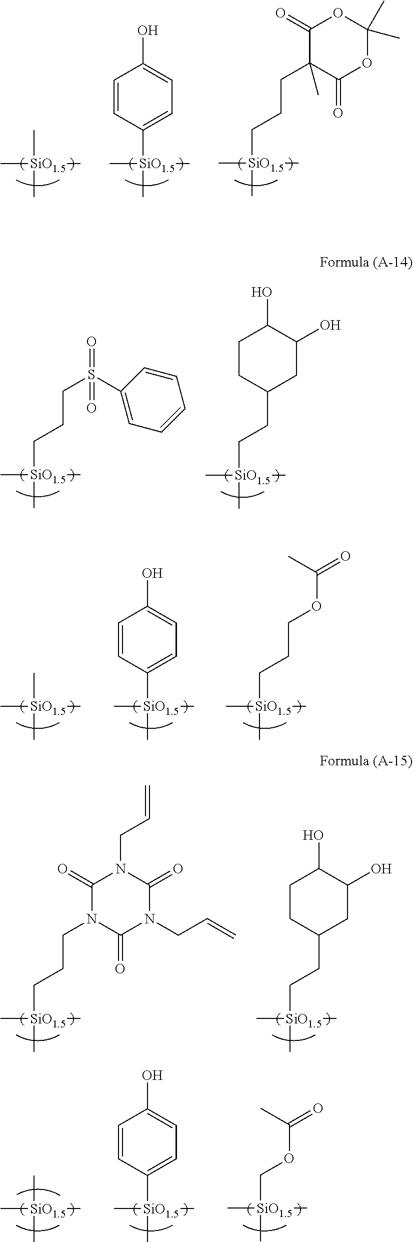

As the hydrolysis-condensate of the hydrolysable silane (polyorganosiloxane), a condensate having a weight average molecular weight of 1,000 to 1,000,000 or 1,000 to 100,000 can be obtained. The molecular weight is determined by GPC analysis in terms of polystyrene.

The GPC analysis can be performed, for example, by a GPC apparatus (trade name: HLC-8220GPC, manufactured by Tosoh Corporation) and a GPC column (trade name: Shodex KF803L, KF802, and KF801, manufactured by Showa Denko K.K.) using tetrahydrofuran as an eluent (elution solvent) and polystyrene (manufactured by Showa Denko K.K.) as a standard sample at a column temperature of 40° C. and a flow rate (flow speed) of 1.0 mL/min.

In hydrolysis of an alkoxysilyl group, an acyloxysilyl group, or a halogenated silyl group, water is used in an amount of 0.5 mol to 100 mol, and preferably 1 mol to 10 mol, per mole of a hydrolyzable group.

A hydrolysis catalyst can be used in an amount of 0.001 to 10 mol, and preferably 0.001 to 1 mol, per mole of the hydrolyzable group.

The reaction temperature during hydrolysis and condensation is typically 20 to 80° C.

The hydrolysis may be complete hydrolysis or partial hydrolysis. In other words, a hydrolysate and a monomer may remain in the hydrolysis-condensate.

During hydrolysis and condensation, a catalyst may be used.

The hydrolysis catalyst is an aqueous solution of an alkaline substance. Examples of the alkaline substance include organic bases and inorganic bases.

Examples of the organic base as the hydrolysis catalyst include pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base include ammonia, sodium hydroxide, potassium hydroxide, barium hydroxide, and calcium hydroxide. One type of the inorganic base may be used or two or more types thereof may be used at the same time.

Examples of an organic solvent used in hydrolysis include aliphatic hydrocarbon-based solvents such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon-based solvents such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, and trimethylbenzene; monoalcohol-based solvents such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonylalcohol, 2,6-dimethyl heptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenyl methyl carbinol, diacetone alcohol, and cresol; polyhydric alcohol-based solvents such as ethylene glycol, propylene glycol, 1,3-butylene glycol, pentanediol-2,4, 2-methyl pentanediol-2,4, hexanediol-2,5, heptanediol-2,4, 2-ethyl hexanediol-1,3, diethylene glycol, dipropylene glycol, triethylene glycol, tripropylene glycol, and glycerol; ketone-based solvents such as acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethyl nonanone, cyclohexanone, methylcyclohexanone, 2,4-pentanedione, acetonylacetone, diacetone alcohol, acetophenone, and fenchone; ether-based solvents such as ethyl ether, i-propyl ether, n-butyl ether, n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, propylene glycol monomethyl ether, propylene glycol monoethyl ether, propylene glycol monopropyl ether, propylene glycol monobutyl ether, propylene glycol monomethyl ether acetate, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyl tetrahydrofuran; ester-based solvents such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents such as N-methylformamide, N,N-dimethylformamide, N,N-diethylformamide, acetamide, N-methylacetamide, N,N-dimethylacetamide, N-methylpropionamide, and N-methylpyrrolidone; and sulfur-containing solvents such as dimethyl sulfide, diethyl sulfide, thiophene, tetrahydrothiophene, dimethyl sulfoxide, sulfolane, and 1,3-propanesultone. One type of the solvent may be used or two or more types thereof may be used in combination.

In particular, ketone-based solvents such as acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethyl nonanone, cyclohexanone, methylcyclohexanone, 2,4-pentanedione, acetonylacetone, diacetone alcohol, acetophenone, and fenchone are preferable in terms of storage stability of a solution.

An epoxy group in the hydrolysis-condensate is ring-opened by an inorganic acid or a cation exchange resin, to produce a dihydroxy group. This inorganic acid may be added in a form of aqueous solution of the inorganic acid. The aqueous solution of the inorganic acid may be used in a concentration of about 0.01 M to about 10 M. Examples of the inorganic acid include hydrochloric acid, nitric acid, sulfuric acid, hydrofluoric acid, and phosphoric acid.

Examples of the cation exchange resin include a strong acidic cation exchange resin (e.g., sulfonic acid ion exchange resin) and a weak acidic cation exchange resin (e.g., carboxylic acid ion exchange resin).

A proton of the inorganic acid or the cation exchange resin functions as a catalyst in a ring opening reaction of an epoxy group. In the present invention, the inorganic acid or the cation exchange resin is added to a reaction system containing the hydrolysis-condensate produced by hydrolysis and condensation by the aqueous solution of the alkaline substance. Therefore, the inorganic acid or the cation exchange resin is consumed for neutralization of remaining alkaline substance. When the proton used in the ring opening reaction of an epoxy group is added in an amount of 0.01 to 100% by mole relative to the amount of the epoxy group, a dihydroxy group is produced. In consideration of consumption amount for neutralization of the alkaline substance, the proton may be added in an amount of 0.01 to 1,000% by mole, 0.01 to 500% by mole, 0.01 to 300% by mole, or 0.01 to 100% by mole.

In the present invention, the inorganic acid or the cation exchange resin is added, and an anion exchange resin may be used for removal of anions. Examples of the anion exchange resin include a strong basic anion exchange resin (e.g., quaternary ammonium ion exchange resin) and a weak basic anion exchange resin (e.g., polyamine ion exchange resin).

The cation exchange resin and the anion exchange resin can be easily removed from the reaction system by filtration.

In the present invention, a crosslinkable compound may be further contained.

Examples of the crosslinkable compound used in the present invention include a crosslinkable compound containing a cyclic structure having an alkoxymethyl group or a hydroxymethyl group or a crosslinkable compound having a blocked isocyanate group.

As an alkoxymethyl group, methoxymethyl group may be preferably used.

Examples of such a crosslinkable compound include a melamine-based compound, a substituted urea-based compound, and polymers thereof. The crosslinkable compound is preferably a crosslinker having at least two crosslinking-forming substituents. Examples thereof include compounds such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, and methoxymethylated thiourea. A condensate of the compounds may also be used. Tetramethoxymethyl glycoluril is available as powderlink 1174 (PL-LI) from Mitsui Cytec Ltd.

As the crosslinker, a crosslinker having high heat resistance may be used. As the crosslinker having high heat resistance, a compound containing a crosslinking-forming sub stituent having an aromatic ring (e.g., a benzene ring or a naphthalene ring) in the molecule may be preferably used.

Examples of the compound include a compound having a partial structure of Formula (4) below, and a polymer or an oligomer having a repeating unit of Formula (5) below.

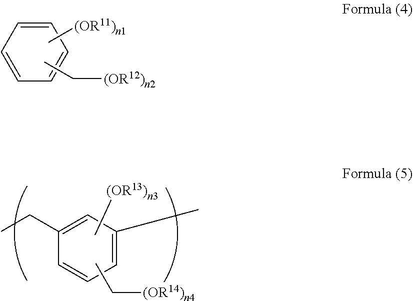

In Formula (4), R¹¹ and R¹² are each independently a hydrogen atom, a C₁₋₁₀ alkyl group, or a C₆₋₂₀ aryl group, n1 is an integer of 1 to 4, n2 is an integer of 1 to (5-n1), and n1+n2 is an integer of 2 to 5.

In Formula (5), R¹³ is a hydrogen atom or a C₁₋₁₀ alkyl group, R¹⁴ is a C₁₋₁₀ alkyl group, n3 is an integer of 1 to 4, n4 is an integer of 0 to (4-n3), and n3+n4 is an integer of 1 to 4.

The oligomer and polymer having 2 to 100 or 2 to 50 repeating unit structures may be used. Examples of the alkyl group and aryl group include those exemplified above.

Examples of the compound of Formula (4) and the polymer and oligomer of Formula (5) include as follows.

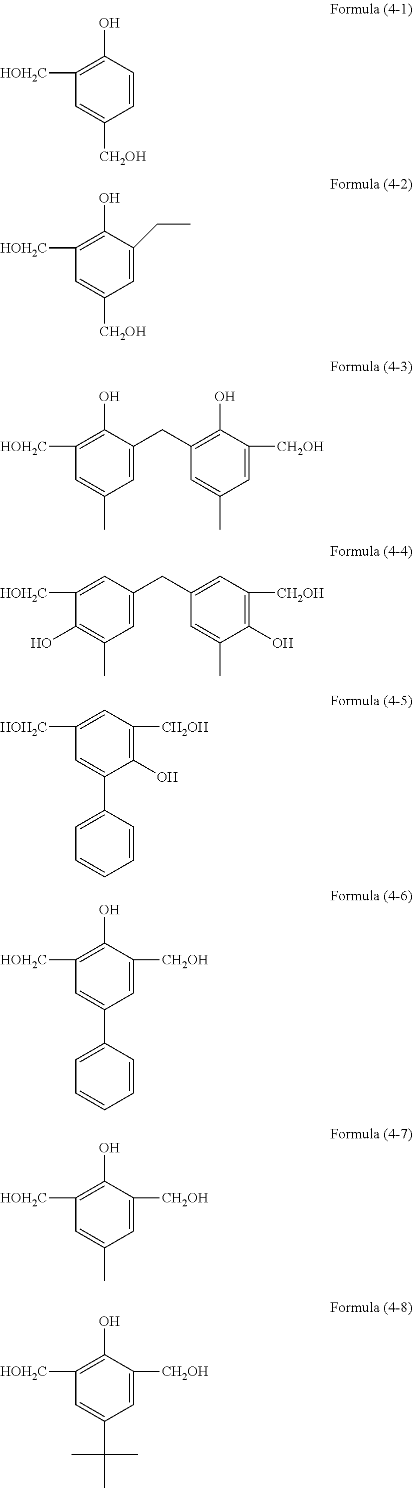

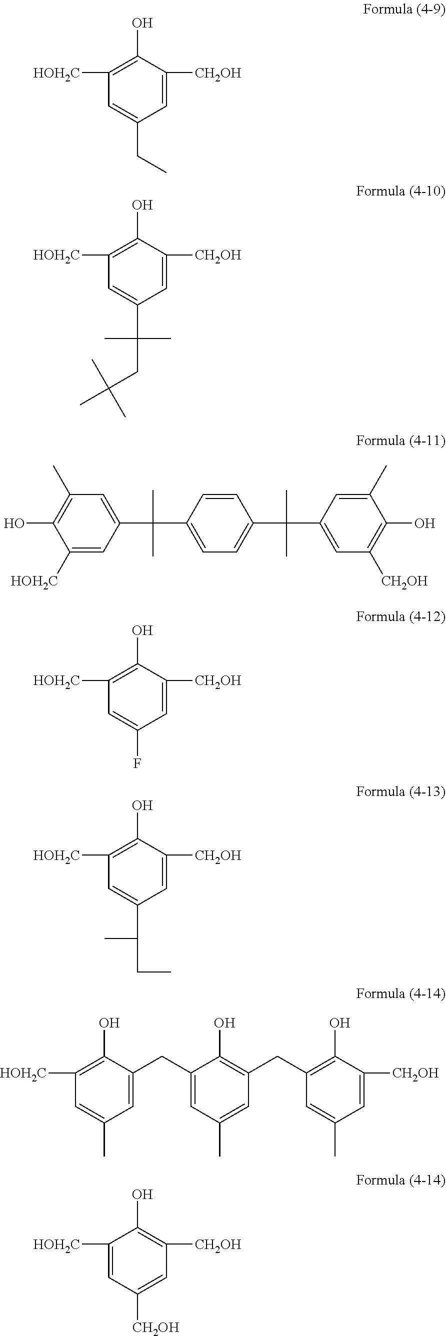

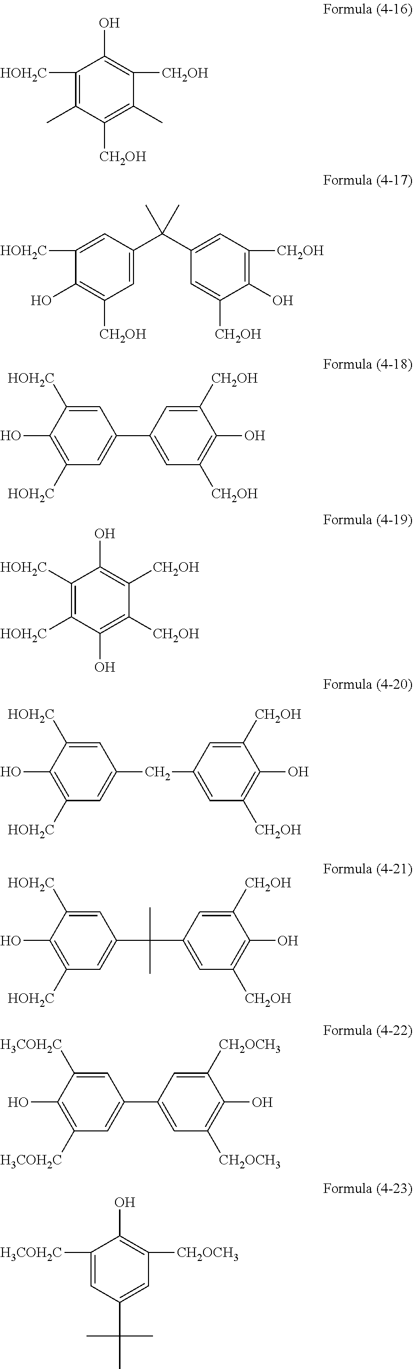

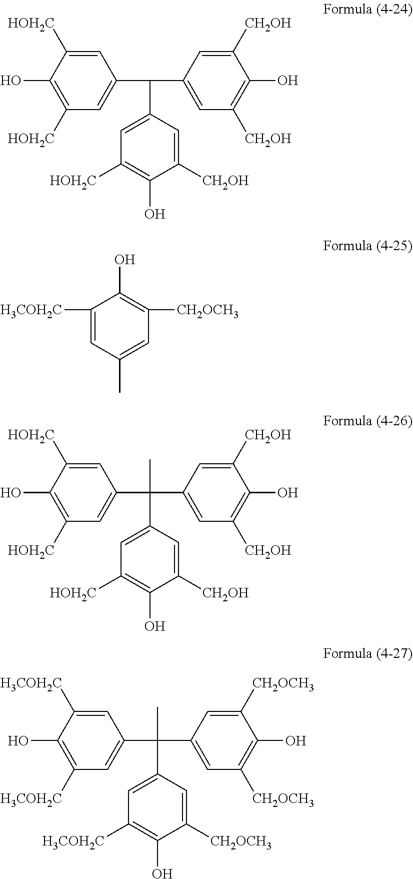

The aforementioned compounds are available as products from Asahi Organic Chemicals Industry Co., Ltd., and Honshu Chemical Industry Co., Ltd. Among the crosslinkers, for example, the compound of Formula (4-21) is available as trade name TM-BIP-A available from Asahi Organic Chemicals Industry Co., Ltd. The compound of Formula (4-22) is available as trade name TMOM-BP available from Honshu Chemical Industry Co., Ltd.

The amount of crosslinkable compound to be added varies depending on a coating solvent to be used, an underlying substrate to be used, a solution viscosity to be required, and a film form to be required, and is 0.001 to 80% by mass, preferably 0.01 to 50% by mass, and further preferably 0.05 to 40% by mass, relative to the amount of whole solid content. The crosslinker may cause a crosslinking reaction due to self-condensation. However, when the aforementioned polymer of the present invention has a crosslinkable substituent, the crosslinker may cause a crosslinking reaction with the crosslinkable substituent.

To promote the crosslinking reaction, the resist underlayer film-forming composition used in the present invention may further contain an acid (acidic compound). Examples of the acid (acidic compound) include camphorsulfonic acid, citric acid, p-toluenesulfonic acid, pyridinium p-toluenesulfonic acid, trifluoromethanesulfonic acid, salicylic acid, sulfosalicylic acid, pyridinium-sulfosalicylic acid, 4-chlorobenzenesulfonic acid, pyridinium-4-chlorobenzenesulfonic acid, 4-hydroxybenzenesulfonic acid, pyridinium-4-hydroxybenzenesulfonic acid, benzenedisulfonic acid, pyridinium-benzenedisulfonic acid, benzoic acid, hydroxybenzoic acid, 1-naphthalenesulfonic acid, and pyridinium-1-naphthalenesulfonic acid. One type of the crosslinking catalyst may be used alone or two or more types thereof may be used in combination. The acid (acidic compound) may be used in an amount of 0.01 to 10 parts by mass, 0.05 to 5 parts by mass, 0.1 to 3 parts by mass, or 0.3 to 2 parts by mass, or 0.5 to 1 part by mass, relative to 100 parts by mass of the condensate (polyorganosiloxane).

The resist underlayer film-forming composition of the present invention may further contain an acid generator. Examples of the acid generator include a thermal acid generator and a photoacid generator. In particular, the photoacid generator generates an acid during exposure of a resist. For this reason, the acidity of the underlayer film can be adjusted. This is one of methods for adjusting the acidity of the underlayer film to the acidity of a resist as an upper layer. When the acidity of the underlayer film is adjusted, a resist pattern profile formed in the upper layer can be adjusted.

Examples of the photoacid generator contained in the resist underlayer film-forming composition of the present invention include onium salt compounds, sulfonimide compounds, and di sulfonyldiazomethane compounds.

Examples of the onium salt compounds include iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds such as triphenylsulfonium hexafluoroantimonate, triphenylsulfonium nonafluoro-n-butanesulfonate, triphenylsulfonium camphorsulfonate, and triphenylsulfonium trifluoromethanesulfonate.

Examples of the sulfonimide compounds include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide.

Examples of the disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

One type of the photoacid generator may be used alone or two or more types thereof may be used in combination. When the photoacid generator is used, the amount thereof is 0.01 to 5 parts by mass, 0.1 to 3 parts by mass, or 0.5 to 1 part by mass, relative to 100 parts by mass of the condensate (polyorganosiloxane).

The resist underlayer film-forming composition of the present invention may further contain a surfactant. The surfactant is effective for suppressing generation of pinholes and striations during applying the resist underlayer film-forming composition of the present invention to a substrate.

Examples of the surfactant contained in the resist underlayer film-forming composition of the present invention include nonionic surfactants including polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine surfactants including trade name Eftop EF301, EF303, and EF352 (available from Tohkem Products Corporation), trade name MEGAFACE F171, F173, R-08, R-30, R-30N, and R-40LM (available from DIC Corporation), Fluorad FC430 and FC431 (available from Sumitomo 3M Limited), and trade name AsahiGuard AG710, and Surflon S-382, SC101, SC102, SC103, SC104, SC105, and SC106 (available from Asahi Glass Co., Ltd.); and organosiloxane polymer KP341 (available from Shin-Etsu Chemical Co., Ltd.). The surfactants may be used alone or two or more types thereof may be used in combination. When the surfactant is used, the amount thereof is 0.0001 to 5 parts by mass, 0.001 to 1 part by mass, or 0.01 to 0.5 parts by mass, relative to 100 parts by mass of the condensate (polyorganosiloxane).

To the resist underlayer film-forming composition of the present invention, a rheology modifier, an adhesion adjuvant, or the like may be added. The rheology modifier is effective for improving the flowability of the underlayer film-forming composition. The adhesion adjuvant is effective for improving the adhesion between a semiconductor substrate or a resist and the underlayer film.

To the resist underlayer film-forming composition of the present invention, a bisphenol S or a bisphenol S derivative may be added as an additive. The amount of the bisphenol S or bisphenol S derivative is 0.01 to 20 parts by mass, 0.01 to 10 parts by mass, or 0.01 to 5 parts by mass, relative to 100 parts by mass of polyorganosiloxane.

Preferable examples of the bisphenol S or the bisphenol S derivative include as follows.

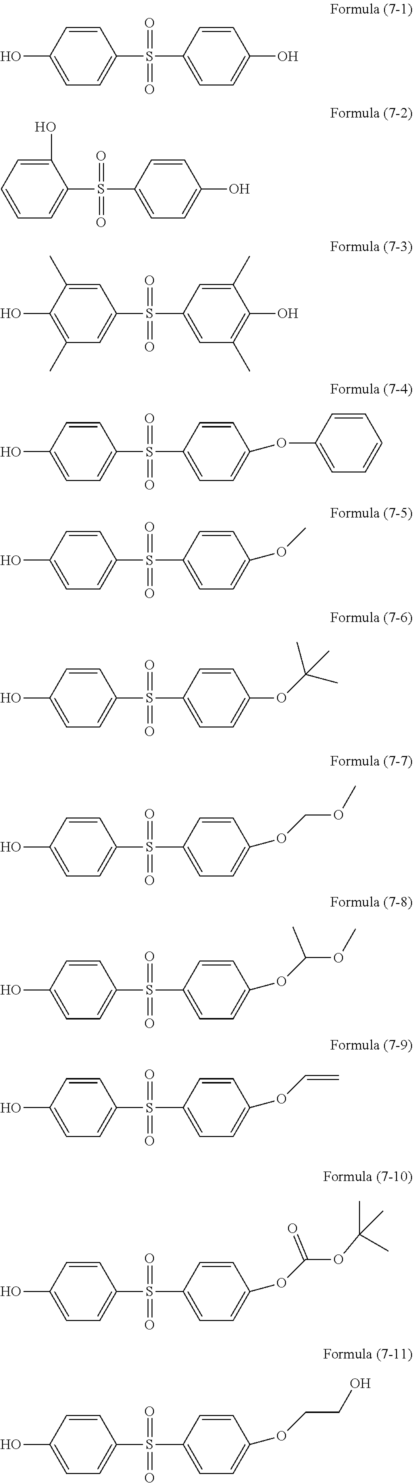

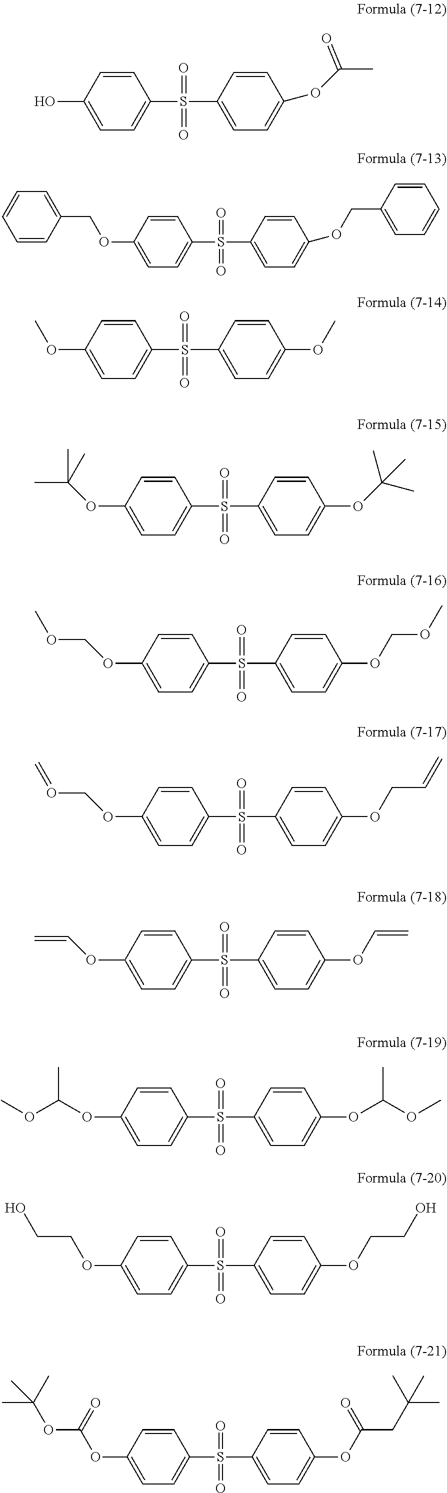

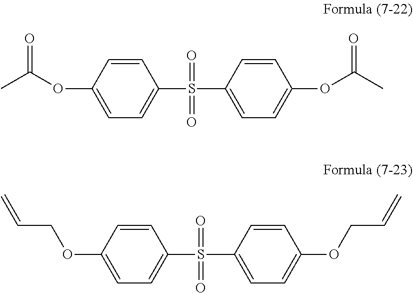

The solvent used for the resist underlayer film-forming composition of the present invention may be used without particular limitation as long as it is a solvent capable of dissolving the solid content. Examples of such a solvent include methyl cellosolve acetate, ethyl cellosolve acetate, propylene glycol, propylene glycol monomethyl ether, propylene glycol monoethyl ether, methylisobutyl carbinol, propylene glycol monobutyl ether, propylene glycol monomethyl ether acetate, propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol monoethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropinoate, methyl 2-hydroxy-3-methylbutyrate, ethyl methoxyacetate, ethyl ethoxyacetate, methyl 3-methoxypropinoate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, toluene, xylene, methyl ethyl ketone, methyl propyl ketone, methyl butyl ketone, 2-heptanone, 3-heptanone, 4-heptanone, cyclohexanone, N,N-dimethylformamide, N-methylacetamide, N,N-dimethylacetamide, N-methylpyrrolidone, 4-methyl-2-pentanol, and γ-butyrolactone. The solvents may be used alone or two or more types thereof may be used in combination.

Hereinafter, the use of the resist underlayer film-forming composition of the present invention will be described.

The resist underlayer film-forming composition of the present invention is applied to a substrate used in production of a semiconductor device (e.g., a silicon wafer substrate, a silicon/silicon dioxide-coating substrate, a silicon nitride substrate, a glass substrate, an ITO substrate, a polyimide substrate, and a low-dielectric constant material (low-k material)-coating substrate) by an appropriate coating method such as a spinner and a coater, and baked to form a resist underlayer film. A baking condition is appropriately selected from a baking temperature of 80° C. to 250° C. and a baking time of 0.3 minutes to 60 minutes. It is preferable that the baking temperature be 150° C. to 250° C. and the baking time be 0.5 to 2 minutes. Herein, the thickness of the formed underlayer film is, for example, 10 to 1,000 nm, 20 to 500 nm, 30 to 300 nm, or 50 to 100 nm.

For example, a layer of a photoresist is then formed on the resist underlayer film. The layer of a photoresist can be formed by a known method, that is, by applying a solution of a photoresist composition to the underlayer film followed by baking. The film thickness of the photoresist is, for example, 50 to 10,000 nm, 100 to 2,000 nm, or 200 to 1,000 nm.

In the present invention, an organic underlayer film can be formed on a substrate, the resist underlayer film of the present invention can be formed on the organic underlayer film, and the photoresist can be applied to the resist underlayer film. In order to prevent pattern collapse due to a decrease in pattern width of the photoresist, the film thickness of the photoresist is decreased. In such a case, the substrate can be processed by appropriate selection of etching gas. For example, when a fluorine-containing gas that achieves sufficiently high etching rate for the photoresist is selected as an etching gas, the resist underlayer film of the present invention can be processed. When an oxygen-containing gas that achieves sufficiently high etching rate for the resist underlayer film of the present invention is selected as an etching gas, the organic underlayer film can be processed. When a fluorine-based gas that achieves sufficiently high etching rate for the organic underlayer film is selected as an etching gas, the substrate can be processed.

The photoresist formed on the resist underlayer film of the present invention is not particularly limited as long as it is sensitive to light used in exposure. Any of a negative photoresist and a positive photoresist can be used. Examples of the photoresist include a positive photoresist including a novolac resin and 1,2-naphthoquinone diazidesulfonic acid ester; a chemically amplified photoresist including a binder having a group that is decomposed by an acid to increase the alkali dissolution rate, and a photoacid generator; a chemically amplified photoresist including a low molecular compound that is decomposed by an acid to increase the alkali dissolution rate of the photoresist, an alkali-soluble binder, and a photoacid generator; and a chemically amplified photoresist including a binder having a group that is decomposed by an acid to increase the alkali dissolution rate, a low molecular compound that is decomposed by an acid to increase the alkali dissolution rate of the photoresist, and a photoacid generator. Specific examples thereof include trade name APEX-E available from Shipley Company L.L.C., trade name PAR710 available from Sumitomo Chemical Co., Ltd., and trade name SEPR430 available from Shin-Etsu Chemical Co., Ltd. Further examples thereof include fluorine atom-containing polymer-based photoresists described in Proc. SPIE, Vol. 3999, 330-334 (2000), Proc. SPIE, Vol. 3999, 357-364 (2000), and Proc. SPIE, Vol. 3999, 365-374 (2000).

Next, exposure through a predetermined mask is carried out. In the exposure, a KrF excimer laser (wavelength: 248 nm), an ArF excimer laser (wavelength: 193 nm), a F2 excimer laser (wavelength: 157 nm), or the like, can be used. After the exposure, post exposure bake may be carried out, if necessary. The post exposure bake is carried out under conditions appropriately selected from a heating temperature of 70° C. to 150° C. and a heating time of 0.3 to 10 minutes.

In the present invention, a resist for electron beam lithography or a resist for EUV lithography can be used as a resist instead of the photoresist. As an electron beam resist, any of a negative resist and a positive resist can be used. Examples thereof include a chemically amplified resist including an acid generator and a binder having a group that is decomposed by an acid to change the alkali dissolution rate; a chemically amplified resist including an alkali-soluble binder, an acid generator, and a low molecular compound that is decomposed by an acid to change the alkali dissolution rate of the resist; a chemically amplified resist including an acid generator, a binder having a group that is decomposed by an acid to change the alkali dissolution rate, and a low molecular compound that is decomposed by an acid to change the alkali dissolution rate of the resist; a nonchemically amplified resist including a binder having a group that is decomposed by an electron beam to change the alkali dissolution rate; and a nonchemically amplified resist including a binder having a moiety that is cleaved by an electron beam to change the alkali dissolution rate. When the electron beam resist is used, a resist pattern can be formed similarly to a case of using an electron beam as an irradiation source and a photoresist.

Subsequently, development by a developer (e.g., alkaline developer) is carried out. For example, when the positive photoresist is used, the photoresist at an exposed area is removed to form a pattern of the photoresist.

Examples of the developer include alkaline aqueous solutions including an aqueous solution of an alkali metal hydroxide such as potassium hydroxide and sodium hydroxide, an aqueous solution of a quaternary ammonium hydroxide such as tetramethylammonium hydroxide, tetraethylammonium hydroxide, and choline, and an aqueous solution of an amine such as ethanolamine, propylamine, and ethylenediamine. Further, a surfactant or the like may be added to the developer. A development condition is appropriately selected from a temperature of 5 to 50° C. and a time of 10 to 600 seconds.

In the present invention, an organic solvent may be used as a developer. After exposure, development by a developer (solvent) is carried out. For example, when the positive photoresist is used, the photoresist at an unexposed area is removed to form a pattern of the photoresist.

Examples of the developer include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl 3-methoxypropionate, ethyl 3-methoxypropionate, ethyl 3-ethoxypropionate, and propyl 3-methoxypropionate. Further, the surfactant or the like may be added to the developer. A development condition is appropriately selected from a temperature of 5 to 50° C. and a time of 10 to 600 seconds.

The resist underlayer film (intermediate layer) of the present invention is removed using the pattern of the formed photoresist (upper layer) as a protective film, and the organic underlayer film (underlayer) is then removed using a film including the patterned photoresist and the resist underlayer film (intermediate layer) of the present invention as a protective film. Finally, the semiconductor substrate is processed using the patterned resist underlayer film (intermediate layer) of the present invention and the organic underlayer film (underlayer) as protective films.

The resist underlayer film (intermediate layer) of the present invention at an area where the photoresist is removed is removed by dry etching, to expose the semiconductor substrate. In the dry etching of the resist underlayer film of the present invention, a gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, or dichloroborane may be used. In the dry etching of the resist underlayer film, a halogen-containing gas is preferably used. In general, a photoresist formed from an organic substance is unlikely to be removed by dry etching by the halogen-containing gas. However, the resist underlayer film of the present invention containing a large amount of silicon atom is rapidly removed by dry etching by the halogen-containing gas. Therefore, the dry etching by the halogen-containing gas can suppress a decrease in film thickness of the photoresist due to dry etching of the resist underlayer film. Accordingly, the photoresist can be used as a thin film. In the dry etching of the resist underlayer film, a fluorine-containing gas is preferable. Examples thereof include tetrafluoromethane (CF₄), perfluorocyclobutane (C₄F₈), perfluoropropane (C₃F₈), trifluoromethane, and difluoromethane (CH₂F₂).

The organic underlayer film is removed using a film including the patterned photoresist and the resist underlayer film of the present invention as a protective film. It is preferable that the organic underlayer film (underlayer) be dry etched by an oxygen-containing gas. This is because the resist underlayer film of the present invention containing a large amount of silicon atom is unlikely to be removed by dry etching by the oxygen-containing gas.

The semiconductor substrate is then processed. It is preferable that the semiconductor substrate be processed by dry etching by the fluorine-containing gas.

Finally, the resist underlayer film is removed. In the removal of the resist underlayer film, dry etching or wet etching is often used. In dry etching of the resist underlayer film (intermediate layer), a fluorine-containing gas is particularly preferable. Examples of the fluorine-containing gas include tetrafluoromethane (CF₄), perfluorocyclobutane (C₄F₈), perfluoropropane (C₃F₈), trifluoromethane, and difluoromethane (CH₂F₂). Examples of a chemical solution used in wet etching of the resist underlayer film (intermediate layer) include hydrofluoric acid, buffered hydrofluoric acid, sulfuric acid/hydrogen peroxide solution, and ammonia/hydrogen peroxide solution.

On an upper layer of the resist underlayer film of the present invention, an organic anti-reflective coating may be formed before formation of the photoresist. An anti-reflective coating composition used in the anti-reflective coating may be optionally selected from anti-reflective coating compositions conventionally used in a lithography process and used without particular limitation. The anti-reflective coating may be formed by a conventionally used method, for example, by coating by a spinner or a coater and baking.

The substrate to which the resist underlayer film-forming composition of the present invention is applied may have an organic or inorganic anti-reflective coating that is formed by a CVD method or the like on a surface of the substrate. On the anti-reflective coating, the underlayer film of the present invention may also be formed.

The resist underlayer film formed from the resist underlayer film-forming composition of the present invention may absorb light used in a lithography process depending on the wavelength of the light. When the resist underlayer film absorbs the light, the resist underlayer film can function as an anti-reflective coating having an effect of reducing light reflected on the substrate. The resist underlying film of the present invention can be also used as a layer for preventing interaction of the substrate with the photoresist, a layer having a function for reducing an adverse influence of a material used for the photoresist or a substance produced during exposure of the photoresist on the substrate, a layer having a function for preventing diffusion of a substance produced from the substrate during heating and baking in the photoresist as the upper layer, a barrier layer for reducing a poisoning effect of the photoresist layer due to a semiconductor substrate dielectric layer, or the like.

The resist underlayer film formed from the resist underlayer film-forming composition is applied to a substrate having a via hole used in a dual damascene process. The resist underlayer film can be used as an embedding material with which the hole is filled without space. Further, the resist underlayer film can also be used as a flatting material for flatting a rough surface of the semiconductor substrate.

An underlayer film of an EUV resist can be used as a hard mask or for a function other than the hard mask. The resist underlayer film-forming composition can be used for an anti-reflective coating of EUV resist underlayer that can prevent reflection of unfavorable exposure light during EUV exposure (wavelength: 13.5 nm) such as UV and DUV (ArF light and KrF light) on a substrate or an interface surface without intermixing with the EUV resist. The reflection can be efficiently prevented by the underlayer of the EUV resist. In a case of using the underlayer as an EUV resist underlayer film, a process can be the same as that in a case of using the photoresist resist underlayer film.

### EXAMPLES

### Synthesis Example 1

1.81 g of 35% by mass tetraethylammonium hydroxide aqueous solution, 2.89 g of water, 47.59 g of isopropyl alcohol, and 95.17 g of methyl isobutyl ketone were placed in a 1,000-mL flask. To the mixed solution, 4.27 g of phenyltrimethoxysilane, 11.51 g of methyltriethoxysilane, and 31.81 g of cyclohexylepoxyethyltrimethoxysilane were added dropwise with stirring by a magnetic stirrer. The cyclohexylepoxyethyltrimethoxysilane was contained in an amount of 60% by mole relative to the total amount of hydrolysable silanes.

After addition, the flask was placed in an oil bath adjusted to 40° C., and a reaction was caused for 240 minutes. Subsequently, 107.59 g of 1 M nitric acid was added to the reaction solution. At 40° C., a cyclohexylepoxy group was ring-opened to obtain a hydrolysis-condensate having a dihydroxy group. 285.52 g of methyl isobutyl ketone and 142.76 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 142.76 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-1). The weight average molecular weight Mw of the polymer measured by GPC in terms of polystyrene was 2,500 and the epoxy value thereof was 0.

### Synthesis Example 2

1.61 g of 35% by mass tetraethylammonium hydroxide aqueous solution, 2.57 g of water, 46.45 g of isopropyl alcohol, and 92.90 g of methyl isobutyl ketone were placed in a 1,000-mL flask. To the mixed solution, 7.92 g of triethoxysilylpropyldiallyl isocyanurate, 10.24 g of methyltriethoxysilane, and 28.30 g of cyclohexylepoxyethyltrimethoxysilane were added dropwise with stirring by a magnetic stirrer. The cyclohexylepoxyethyltrimethoxysilane was contained in an amount of 60% by mole relative to the total amount of hydrolysable silanes. After addition, the flask was placed in an oil bath adjusted to 40° C., and a reaction was caused for 240 minutes. Subsequently, 95.70 g of 1 M nitric acid was added to the reaction solution. At 40° C., a cyclohexylepoxy group was ring-opened to obtain a hydrolysis-condensate having a dihydroxy group. 278.69 g of methyl isobutyl ketone and 139.35 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 139.35 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-2). The weight average molecular weight Mw of the polymer measured by GPC in terms of polystyrene was 2,700 and the epoxy value thereof was 0.

### Synthesis Example 3

1.48 g of 35% by mass tetraethylammonium hydroxide aqueous solution, 2.36 g of water, 39.50 g of isopropyl alcohol, and 79.00 g of methyl isobutyl ketone were placed in a 1,000-mL flask. To the mixed solution, 7.27 g of triethoxysilylpropyldiallyl isocyanurate, 6.27 g of methyltriethoxysilane, 25.97 g of cyclohexylepoxyethyltrimethoxysilane, and 5.03 g of ethoxyethoxyphenyltrimethoxysilane were added dropwise with stirring by a magnetic stirrer. The cyclohexylepoxyethyltrimethoxysilane was contained in an amount of 60% by mole relative to the total amount of hydrolysable silanes. After addition, the flask was placed in an oil bath adjusted to 40° C., and a reaction was caused for 240 minutes. Subsequently, 87.84 g of 1 M nitric acid was added to the reaction solution. At 40° C., a cyclohexylepoxy group was ring-opened to obtain a hydrolysis-condensate having a dihydroxy group. 237.01 g of methyl isobutyl ketone and 118.51 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 118.51 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-3). The weight average molecular weight Mw of the polymer measured by GPC in terms of polystyrene was 2,400 and the epoxy value thereof was 0.

### Synthesis Example 4

1.52 g of 35% by mass tetraethylammonium hydroxide aqueous solution, 2.43 g of water, 40.55 g of isopropyl alcohol, and 81.10 g of methyl isobutyl ketone were placed in a 1,000-mL flask. To the mixed solution, 7.46 g of triethoxysilylpropyldiallyl isocyanurate, 6.43 g of methyltriethoxysilane, 26.66 g of cyclohexylepoxyethyltrimethoxysilane, and 4.37 g of methoxybenzyltrimethoxysilane were added dropwise with stirring by a magnetic stirrer. The cyclohexylepoxyethyltrimethoxysilane was contained in an amount of 60% by mole relative to the total amount of hydrolysable silanes. After addition, the flask was placed in an oil bath adjusted to 40° C., and a reaction was caused for 240 minutes. Subsequently, 90.17 g of 1 M nitric acid was added to the reaction solution. At 40° C., a cyclohexylepoxy group was ring-opened to obtain a hydrolysis-condensate having a dihydroxy group. 243.29 g of methyl isobutyl ketone and 121.65 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 121.65 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-4). The weight average molecular weight Mw of the polymer measured by GPC in terms of polystyrene was 2,600 and the epoxy value thereof was 0.

### Synthesis Example 5

1.61 g of 35% by mass tetraethylammonium hydroxide aqueous solution, 2.57 g of water, 41.20 g of isopropyl alcohol, and 82.39 g of methyl isobutyl ketone were placed in a 1,000-mL flask. To the mixed solution, 7.92 g of triethoxysilylpropyldiallyl isocyanurate, 6.83 g of methyltriethoxysilane, 9.43 g of cyclohexylepoxyethyltrimethoxysilane, 5.48 g of ethoxyethoxyphenyltrimethoxysilane, and 17.02 g of acetoxypropyltrimethoxysilane were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 95.71 g of 1 M nitric acid was added to the reaction solution. At 40° C., a cyclohexylepoxy group was ring-opened to obtain a hydrolysis-condensate having a dihydroxy group. 247.17 g of methyl isobutyl ketone and 123.59 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 123.59 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-5). The weight average molecular weight Mw of the polymer measured by GPC in terms of polystyrene was 2,800 and the epoxy value thereof was 0.

### Synthesis Example 6

1.68 g of 35% by mass tetraethylammonium hydroxide aqueous solution, 2.69 g of water, 44.19 g of isopropyl alcohol, and 88.38 g of methyl isobutyl ketone were placed in a 1,000-mL flask. To the mixed solution, 8.28 g of triethoxysilylpropyldiallyl isocyanurate, 7.14 g of methyltriethoxysilane, 9.86 g of cyclohexylepoxyethyltrimethoxysilane, 5.73 g of ethoxyethoxyphenyltrimethoxysilane, and 18.92 g of acetoxymethyltriethoxysilane were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 100.06 g of 1 M nitric acid was added to the reaction solution. At 40° C., a cyclohexylepoxy group was ring-opened to obtain a hydrolysis-condensate having a dihydroxy group. 265.15 g of methyl isobutyl ketone and 132.58 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 132.58 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-6). The weight average molecular weight Mw of the polymer measured by GPC in terms of polystyrene was 2,800 and the epoxy value thereof was 0.

### Synthesis Example 7

1.61 g of 35% by mass tetraethylammonium hydroxide aqueous solution, 2.58 g of water, 45.73 g of isopropyl alcohol, and 91.47 g of methyl isobutyl ketone were placed in a 1,000-mL flask. To the mixed solution, 7.93 g of triethoxysilylpropyldiallyl isocyanurate, 3.42 g of methyltriethoxysilane, 9.45 g of cyclohexylepoxyethyltrimethoxysilane, 5.49 g of ethoxyethoxyphenyltrimethoxysilane, 18.13 g of acetoxymethyltriethoxysilane, and 6.80 g of bis(triethoxysilyl)ethane were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 95.90 g of 1 M nitric acid was added to the reaction solution. At 40° C., a cyclohexylepoxy group was ring-opened to obtain a hydrolysis-condensate having a dihydroxy group. 274.41 g of methyl isobutyl ketone and 137.20 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 137.20 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-7). The weight average molecular weight Mw of the polymer measured by GPC in terms of polystyrene was 4,300 and the epoxy value thereof was 0.

### Synthesis Example 8

1.70 g of 35% by mass tetraethylammonium hydroxide aqueous solution, 2.72 g of water, 45.82 g of isopropyl alcohol, and 91.65 g of methyl isobutyl ketone were placed in a 1,000-mL flask. To the mixed solution, 8.35 g of triethoxysilylpropyldiallyl isocyanurate, 8.42 g of tetraethoxysilane, 9.95 g of cyclohexylepoxyethyltrimethoxysilane, 5.79 g of ethoxyethoxyphenyltrimethoxysilane, and 19.10 g of acetoxymethyltriethoxysilane were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 101.01 g of 1 M nitric acid was added to the reaction solution. At 40° C., a cyclohexylepoxy group was ring-opened to obtain a hydrolysis-condensate having a dihydroxy group. 274.95 g of methyl isobutyl ketone and 137.47 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 137.47 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-8). The weight average molecular weight Mw of the polymer measured by GPC in terms of polystyrene was 3,800 and the epoxy value thereof was 0.

### Synthesis Example 9

1.72 g of 35% by mass tetraethylammonium hydroxide aqueous solution, 2.75 g of water, 46.04 g of isopropyl alcohol, and 92.08 g of methyl isobutyl ketone were placed in a 1,000-mL flask. To the mixed solution, 8.47 g of triethoxysilylpropyldiallyl isocyanurate, 8.53 g of tetraethoxysilane, 9.98 g of glycidoxypropyltrimethoxysilane, 5.87 g of ethoxyethoxyphenyltrimethoxysilane, and 19.36 g of acetoxymethyltriethoxysilane were added dropwise with stirring by a magnetic stirrer. The glycidoxypropyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 102.39 g of 1 M nitric acid was added to the reaction solution. At 40° C., a glycidoxy group was ring-opened to obtain a hydrolysis-condensate having a dihydroxy group. 276.25 g of methyl isobutyl ketone and 138.12 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 138.12 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-9). The weight average molecular weight Mw of the polymer measured by GPC in terms of polystyrene was 2,800 and the epoxy value thereof was 0.

### Synthesis Example 10

1.77 g of 35% by mass tetraethylammonium hydroxide aqueous solution, 2.82 g of water, 44.88 g of isopropyl alcohol, and 89.76 g of methyl isobutyl ketone were placed in a 1,000-mL flask. To the mixed solution, 7.23 g of (2-methoxy-4-(methoxymethyl)phenoxy)methyltriethoxysilane, 7.48 g of methyltriethoxysilane, 10.34 g of cyclohexylepoxyethyltrimethoxysilane, 6.01 g of ethoxyethoxyphenyltrimethoxysilane, and 19.83 g of acetoxymethyltriethoxysilane were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 104.89 g of 1 M nitric acid was added to the reaction solution. At 40° C., a cyclohexylepoxy group was ring-opened to obtain a hydrolysis-condensate having a dihydroxyl group. 274.95 g of methyl isobutyl ketone and 137.47 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 137.47 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A1). The weight average molecular weight Mw of the polymer measured by GPC in terms of polystyrene was 3,000 and the epoxy value thereof was 0.

### Synthesis Example 11

1.35 g of 35% by mass tetraethylammonium hydroxide aqueous solution, 2.16 g of water, 41.39 g of isopropyl alcohol, and 82.79 g of methyl isobutyl ketone were placed in a 1,000-mL flask. To the mixed solution, 6.64 g of triethoxysilylpropyldiallyl isocyanurate, 5.73 g of methyltriethoxysilane, 7.92 g of cyclohexylepoxyethyltrimethoxysilane, 4.60 g of ethoxyethoxyphenyltrimethoxysilane, and 21.10 g of 5-(triethoxysilyl)hexahydro-4,7-methanoisobenzofuran-1,3-dione were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 80.32 g of 1 M nitric acid was added to the reaction solution. At 40° C., a cyclohexylepoxy group was ring-opened to obtain a hydrolysis-condensate having a dihydroxy group. 248.36 g of methyl isobutyl ketone and 124.18 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 124.18 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-11). The weight average molecular weight Mw of the polymer measured by GPC in terms of polystyrene was 2,400 and the epoxy value thereof was 0.

### Synthesis Example 12

1.26 g of 35% by mass tetraethylammonium hydroxide aqueous solution, 2.01 g of water, 40.62 g of isopropyl alcohol, and 81.23 g of methyl isobutyl ketone were placed in a 1,000-mL flask. To the mixed solution, 6.19 g of triethoxysilylpropyldiallyl isocyanurate, 5.34 g of methyltriethoxysilane, 7.38 g of cyclohexylepoxyethyltrimethoxysilane, 4.29 g of ethoxyethoxyphenyltrimethoxysilane, and 21.71 g of 2,2,5-trimethyl-5-(3-(triethoxysilyl)propyl)-1,3-dioxan-4,6-dione were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 74.86 g of 1 M nitric acid was added to the reaction solution. At 40° C., a cyclohexylepoxy group was ring-opened to obtain a hydrolysis-condensate having a dihydroxy group. 243.70 g of methyl isobutyl ketone and 121.85 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 121.85 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-12). The weight average molecular weight Mw of the polymer measured by GPC in terms of polystyrene was 2,600 and the epoxy value thereof was 0.

### Synthesis Example 13

1.37 g of 35% by mass tetraethylammonium hydroxide aqueous solution, 2.19 g of water, 41.52 g of isopropyl alcohol, and 83.04 g of methyl isobutyl ketone were placed in a 1,000-mL flask. To the mixed solution, 4.17 g of (bicyclo(2,2,1)hept-5-en-yl)triethoxysilane, 5.79 g of methyltriethoxysilane, 8.01 g of cyclohexylepoxyethyltrimethoxysilane, 4.65 g of ethoxyethoxyphenyltrimethoxysilane, and 23.56 g of 2,2,5-trimethyl-5-(3-(triethoxysilyl)propyl)-1,3-dioxan-4,6-dione were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 74.86 g of 1 M nitric acid was added to the reaction solution. At 40° C., a cyclohexylepoxy group was ring-opened to obtain a hydrolysis-condensate having a dihydroxy group. 243.70 g of methyl isobutyl ketone and 121.85 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 121.85 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-13). The weight average molecular weight Mw of the polymer measured by GPC in terms of polystyrene was 2,800 and the epoxy value thereof was 0.

### Synthesis Example 14

1.63 g of 35% by mass tetraethylammonium hydroxide aqueous solution, 2.61 g of water, 40.51 g of isopropyl alcohol, and 81.01 g of methyl isobutyl ketone were placed in a 1,000-mL flask. To the mixed solution, 6.73 g of phenylsulfonylpropyltriethoxysilane, 6.93 g of methyltriethoxysilane, 9.57 g of cyclohexylepoxyethyltrimethoxysilane, 5.56 g of ethoxyethoxyphenyltrimethoxysilane, and 17.27 g of acetoxypropyltrimethoxysilane were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 97.13 g of 1 M nitric acid was added to the reaction solution. At 40° C., a cyclohexylepoxy group was ring-opened to obtain a hydrolysis-condensate having a dihydroxy group. 243.04 g of methyl isobutyl ketone and 121.52 g of water were added to the hydrolysis-condensate. By a liquid separation operation, reaction by-products transferred to an aqueous phase, such as water, nitric acid, and tetraethylammonium nitric acid salt, were removed, and an organic phase was collected. Subsequently, 121.52 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-14). The weight average molecular weight Mw of the polymer measured by GPC in terms of polystyrene was 2,300 and the epoxy value thereof was 0.

### Synthesis Example 15

1.70 g of 35% by mass tetraethylammonium hydroxide aqueous solution, 2.72 g of water, 45.82 g of isopropyl alcohol, and 91.65 g of methyl isobutyl ketone were placed in a 1,000-mL flask. To the mixed solution, 8.35 g of triethoxysilylpropyldiallyl isocyanurate, 8.42 g of tetraethoxysilane, 9.95 g of cyclohexylepoxyethyltrimethoxysilane, 5.79 g of ethoxyethoxyphenyltrimethoxysilane, and 19.10 g of acetoxymethyltriethoxysilane were added dropwise with stirring by a magnetic stirrer. The cyclohexylepoxyethyltrimethoxysilane was contained in an amount of 20% by mole relative to the total amount of hydrolysable silanes. After addition, the flask was placed in an oil bath adjusted to 40° C., and a reaction was caused for 240 minutes. Subsequently, 30 g of cationic exchange resin was added to the reaction solution. At 40° C., a cyclohexylepoxy group was ring-opened to obtain a hydrolysis-condensate having a dihydroxy group. 60 g of anion exchange resin was added. Subsequently, the cation exchange resin and the anion exchange resin were removed by a nylon mesh filter, 137.47 g of propylene glycol monomethyl ether was added, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (A-15). The weight average molecular weight Mw of the polymer measured by GPC in terms of polystyrene was 6,000 and the epoxy value thereof was 0.

### Comparative Synthesis Example 1

1.81 g of 35% by mass tetraethylammonium hydroxide aqueous solution, 2.89 g of water, 47.59 g of isopropyl alcohol, and 95.17 g of methyl isobutyl ketone were placed in a 1,000-mL flask. To the mixed solution, 4.27 g of phenyltrimethoxysilane, 11.51 g of methyltriethoxysilane, and 31.81 g of cyclohexylepoxyethyltrimethoxysilane were added dropwise with stirring by a magnetic stirrer. The cyclohexylepoxyethyltrimethoxysilane was contained in an amount of 60% by mole relative to the total amount of hydrolysable silanes. After addition, the flask was placed in an oil bath adjusted to 40° C., and a reaction was caused for 240 minutes. 285.52 g of methyl isobutyl ketone and 142.76 g of water were added to the hydrolysis-condensate. By a liquid separation operation, reaction by-products transferred to an aqueous phase, such as water and tetraethylammonium hydroxide, were removed, and an organic phase was collected. Subsequently, 142.76 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (B-1). The weight average molecular weight Mw of the polymer measured by GPC in terms of polystyrene was 2,300. The epoxy value thereof showed that 95% or more of epoxy group remained.

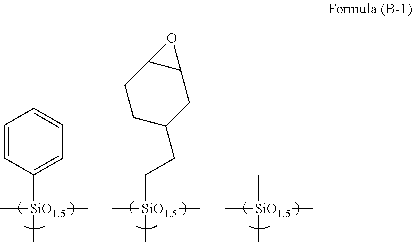

### Comparative Synthesis Example 2

3.20 g of 35% by mass tetraethylammonium hydroxide aqueous solution, 5.12 g of water, 69.91 g of isopropyl alcohol, and 139.81 g of methyl isobutyl ketone were placed in a 1,000-mL flask. To the mixed solution, 7.55 g of phenyltrimethoxysilane, 57.67 g of methyltriethoxysilane, and 4.69 g of cyclohexylepoxyethyltrimethoxysilane were added dropwise with stirring by a magnetic stirrer. The cyclohexylepoxyethyltrimethoxysilane was contained in an amount of 5% by mole relative to the total amount of hydrolysable silanes. After addition, the flask was placed in an oil bath adjusted to 40° C., and a reaction was caused for 240 minutes. Subsequently, 190.27 g of 1 M nitric acid was added to the reaction solution. At 40° C., a cyclohexylepoxy group was ring-opened to obtain a hydrolysis-condensate having a dihydroxy group. 419.44 g of methyl isobutyl ketone and 209.72 g of water were added to the hydrolysis-condensate. By a liquid separation operation, reaction by-products transferred to an aqueous phase, such as water and tetraethylammonium hydroxide, were removed, and an organic phase was collected. Subsequently, 209.72 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (B-2). The weight average molecular weight Mw of the polymer measured by GPC in terms of polystyrene was 4,000 and the epoxy value thereof was 0.

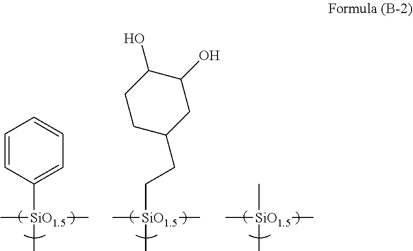

### Comparative Synthesis Example 3

2.96 g of 35% by mass tetraethylammonium hydroxide aqueous solution, 4.73 g of water, 66.01 g of isopropyl alcohol, and 132.02 g of methyl isobutyl ketone were placed in a 1,000-mL flask. To the mixed solution, 7.35 g of phenyltrimethoxysilane, 49.54 g of methyltriethoxysilane, and 9.13 g of cyclohexylepoxyethyltrimethoxysilane were added dropwise with stirring by a magnetic stirrer. The cyclohexylepoxyethyltrimethoxysilane was contained in an amount of 10% by mole relative to the total amount of hydrolysable silanes. After addition, the flask was placed in an oil bath adjusted to 40° C., and a reaction was caused for 240 minutes. Subsequently, 175.96 g of 1 M acetic acid was added to the reaction solution. At 40° C., a cyclohexylepoxy group was ring-opened to obtain a hydrolysis-condensate having an acetoxy group and a monohydroxyl group. 396.05 g of methyl isobutyl ketone and 198.03 g of water were added to the hydrolysis-condensate. By a liquid separation operation, reaction by-products transferred to an aqueous phase, such as water and tetraethylammonium hydroxide, were removed, and an organic phase was collected. Subsequently, 198.03 g of propylene glycol monomethyl ether was added to the organic phase, and methyl isobutyl ketone, methanol, ethanol, and water were distilled off under reduced pressure, to concentrate the reaction solution. As a result, an aqueous solution of a hydrolysis-condensate (polymer) was obtained. To the aqueous solution, propylene glycol monoethyl ether was added to adjust the amount of the hydrolysis-condensate in terms of solid content at 140° C. to 20% by mass in the solvent ratio of propylene glycol monomethyl ether of 100%. The obtained polymer corresponded to Formula (B-3). The weight average molecular weight Mw of the polymer measured by GPC in terms of polystyrene was 3,800 and the epoxy value thereof was 0.

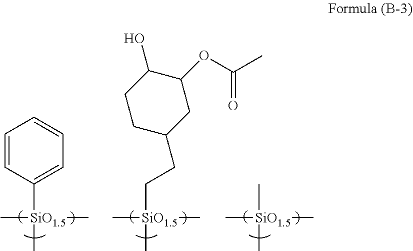

(Preparation of Si-Containing Resist Underlayer Film)

The hydrolysis-condensate (Si-containing polymer) obtained in each of Synthesis Examples 1 to 15 and Comparative Synthesis Examples 1 to 3, an acid, and a solvent were mixed at a ratio shown in Table 1 and 2, and the mixture was filtrated through a 0.1 μm-fluororesin filter, to prepare a resist underlayer film-forming composition. The addition ratio of polymer in Table 1 and 2 represents the amount of the added polymer, but not the amount of a polymer solution.

In Tables below, PPTS means pyridinium-p-toluenesulfonic acid. Trade name TAG-2689 means a thermal acid generator available from King Industries Inc., (the component thereof is an ammonium salt of trifluorosulfonic acid). A crosslinkable compound PL-LI means trade name powderlink 1174 available from Mitsui Cytec Ltd., which is tetramethoxymethyl glycoluril. Among crosslinkable compounds, Trade name TMOM-BP available from Honshu Chemical Industry Co., Ltd means a compound of Formula (4-22), and Trade name TM-BIP-A available from Asahi Organic Chemicals Industry Co., Ltd. means a compound of Formula (4-21). PGME means propylene glycol monomethyl ether, and PGMEA means propylene glycol monomethyl ether acetate.

TABLE 1

| | Polymer | Acid catalyst | Crosslinker | Solvent | |
|---|---|---|---|---|---|
| Example 1 | Synthesis Example 1 | PPTS | PL-LI | PGME | PGMEA |
| (part by mass) | 4 | 0.2 | 0.8 | 70 | 30 |
| Example 2 | Synthesis Example 2 | PPTS | PL-LI | PGME | PGMEA |
| (part by mass) | 4 | 0.2 | 0.8 | 70 | 30 |
| Example 3 | Synthesis Example 3 | PPTS | PL-LI | PGME | PGMEA |
| (part by mass) | 4 | 0.2 | 0.8 | 70 | 30 |
| Example 4 | Synthesis Example 4 | PPTS | PL-LI | PGME | PGMEA |
| (part by mass) | 4 | 0.2 | 0.8 | 70 | 30 |
| Example 5 | Synthesis Example 5 | PPTS | PL-LI | PGME | PGMEA |
| (part by mass) | 4 | 0.2 | 0.8 | 70 | 30 |
| Example 6 | Synthesis Example 6 | PPTS | PL-LI | PGME | PGMEA |
| (part by mass) | 4 | 0.2 | 0.8 | 70 | 30 |
| Example 7 | Synthesis Example 7 | PPTS | PL-LI | PGME | PGMEA |
| (part by mass) | 4 | 0.2 | 0.8 | 70 | 30 |
| Example 8 | Synthesis Example 8 | PPTS | PL-LI | PGME | PGMEA |
| (part by mass) | 4 | 0.2 | 0.8 | 70 | 30 |
| Example 9 | Synthesis Example 9 | PPTS | PL-LI | PGME | PGMEA |
| (part by mass) | 4 | 0.2 | 0.8 | 70 | 30 |
| Example 10 | Synthesis Example 10 | PPTS | PL-LI | PGME | PGMEA |
| (part by mass) | 4 | 0.2 | 0.8 | 70 | 30 |

TABLE 2

| | Polymer | Acid catalyst | Crosslinker | Solvent | |
|---|---|---|---|---|---|
| Example 11 | Synthesis Example 11 | PPTS | PL-LI | PGME | PGMEA |
| (part by mass) | 4 | 0.2 | 0.8 | 70 | 30 |
| Example 12 | Synthesis Example 12 | PPTS | PL-LI | PGME | PGMEA |
| (part by mass) | 4 | 0.2 | 0.8 | 70 | 30 |
| Example 13 | Synthesis Example 13 | PPTS | PL-LI | PGME | PGMEA |
| (part by mass) | 4 | 0.2 | 0.8 | 70 | 30 |
| Example 14 | Synthesis Example 14 | PPTS | PL-LI | PGME | PGMEA |
| (part by mass) | 4 | 0.2 | 0.8 | 70 | 30 |
| Example 15 | Synthesis Example 15 | PPTS | PL-LI | PGME | PGMEA |
| (part by mass) | 4 | 0.2 | 0.8 | 70 | 30 |
| Example 16 | Synthesis Example 1 | PPTS | TMOM-BP | PGME | PGMEA |
| (part by mass) | 4 | 0.2 | 0.8 | 70 | 30 |
| Example 17 | Synthesis Example 2 | TAG2689 | PL-LI | PGME | PGMEA |
| (part by mass) | 4 | 0.2 | 0.8 | 70 | 30 |
| Example18 | Synthesis Example 3 | PPTS | TM-BIP-A | PGME | PGMEA |
| (part by mass) | 4 | 0.2 | 0.8 | 70 | 30 |
| Comparative | Comparative Synthesis | PPTS | PL-LI | PGME | PGMEA |
| Example 1 | Example 1 | | | | |
| (part by mass) | 4 | 0.2 | 0.8 | 70 | 30 |
| Comparative | Comparative Synthesis | PPTS | PL-LI | PGME | PGMEA |
| Example 2 | Example 2 | | | | |
| (part by mass) | 4 | 0.2 | 0.8 | 70 | 30 |
| Comparative | Comparative Synthesis | PPTS | PL-LI | PGME | PGMEA |
| Example 3 | Example 3 | | | | |
| (part by mass) | 4 | 0.2 | 0.8 | 70 | 30 |

(Preparation of Organic Underlayer Film)

In a 100-mL four-neck flask, carbazole (6.69 g, 0.040 mol, available from Tokyo Chemical Industry Co., Ltd.), 9-fluorenone (7.28 g, 0.040 mol, available from Tokyo Chemical Industry Co., Ltd.), and p-toluenesulfonic acid monohydrate (0.76 g, 0.0040 mol, available from Tokyo Chemical Industry Co., Ltd.) were placed under nitrogen. Further, 1,4-dioxane (6.69 g, available from Kanto Chemical Co., Inc.) was added. The mixture was stirred, heated to 100° C., and then dissolved to start polymerization. After 24 hours, the resultant was allowed to cool to 60° C., and diluted with chloroform (34 g, available from Kanto Chemical Co., Inc.). In methanol (168 g, available from Kanto Chemical Co., Inc.), reprecipitation was caused. The obtained precipitate was collected by filtration, and dried at 80° C. for 24 hours by a reduced-pressure dryer to obtain 9.37 g of target polymer (Formula (C-1), hereinafter abbreviated as PCzFL).

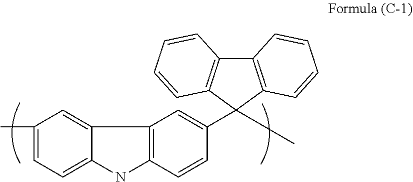

A result of measurement of PCzFL by ¹H-NMR is as follows. ¹H-NMR (400 MHz, DMSO-d₆): δ 7.03-7.55 (br, 12H), δ 7.61-8.10 (br, 4H), δ 11.18 (br, 1H)

The weight average molecular weight Mw measured by GPC in terms of polystyrene of PCzFL was 2,800 and the degree of distribution Mw/Mn thereof was 1.77.

In 20 g of the obtained resin, 3.0 g of tetramethoxymethyl glycoluril (trade name powderlink 1174 available from Mitsui Cytec Ltd.) as a crosslinker, 0.30 g of pyridinium p-toluenesulfonate as a catalyst, and 0.06 g of MEGAFACE R-30 (trade name, available from Dainippon Ink and Chemicals, Inc.) as a surfactant were mixed. The mixture was dissolved in 88 g of propylene glycol monomethyl ether acetate to obtain a solution. The solution was subjected to filtration through a polyethylene microfilter with a pore diameter of 0.10 μm, and then through a polyethylene microfilter with a pore diameter of 0.05 μm to prepare a solution of an organic underlayer film-forming composition for a lithography process including a multilayer film.

(Solvent Resistance Test)

The resist underlayer film-forming composition prepared in each of Examples 1 to 18 and Comparative Examples 1 to 3 was applied to a silicon wafer by a spinner. The resist underlayer film-forming composition was heated at 180° C. for 1 minute on a hot plate to form an Si-containing resist underlayer film. A solvent of propylene glycol monomethyl ether and propylene glycol monomethyl ether acetate at a propylene glycol monomethyl ether to propylene glycol monomethyl ether acetate of 7 to 3 was then applied to the Si-containing resist underlayer film, and then dried by spinning. For changes in film thickness before and after applying the solvent, a pattern profile was evaluated. A case where the change in film thickness was less than 1% is considered to be “good.” A case where the change in film thickness is 1% or more is considered to be “not cured.”

TABLE 3

| | Change in film thickness |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Example 11 | Good |
| Example 12 | Good |
| Example 13 | Good |
| Example 14 | Good |
| Example 15 | Good |
| Example 16 | Good |
| Example 17 | Good |
| Example 18 | Good |
| Comparative Example 1 | Not cured |
| Comparative Example 2 | Not cured |
| Comparative Example 3 | Not cured |

In the evaluation, a case where the change in film thickness is 1% or more is determined to be “not cured.” In Comparative Examples 1 to 3, the change in film thickness is 1% or more. Therefore, curing is not sufficiently promoted, and the resist underlayer film may be dissolved in the solvent for the resist that coats the resist underlayer film as an upper layer and adversely affect the resist layer. In Comparative Examples 1 and 3, a later resist pattern was evaluated.

(Measurement of Dry Etching Rate)

As an etcher and an etching gas used in measurement of dry etching rate, the following etcher and gas were used.

ES401 (available from NIPPON SCIENTIFIC Co., Ltd.): CF₄
RIE-10NR (manufactured by SAMCO INC.): O₂

The Si-containing coating solution prepared in each of Examples 1 to 18 was applied to a silicon wafer by a spinner. The Si-containing coating solution was heated at 180° C. for 1 minute on a hot plate to form an Si-containing resist underlayer film (film thickness: 0.1 μm (for measurement of etching rate by a CF₄ gas), film thickness: 0.1 (for measurement of etching rate by an O₂ gas)).

As an etching gas, a CF₄ gas or an O₂ gas was used in measurement of dry etching rate.

TABLE 4

| | Fluorine-based gas etching | Oxygen-based gas etching |
|---|---|---|
| | rate (nm/min) | rate (nm/min) |
| Example 1 | 26 | 10 |
| Example 2 | 28 | 11 |
| Example 3 | 28 | 12 |
| Example 4 | 28 | 12 |
| Example 5 | 28 | 12 |
| Example 6 | 28 | 11 |
| Example 7 | 28 | 11 |
| Example 8 | 28 | 10 |
| Example 9 | 28 | 10 |
| Example 10 | 26 | 10 |
| Example 11 | 28 | 12 |
| Example 12 | 28 | 12 |
| Example 13 | 26 | 10 |
| Example 14 | 26 | 10 |
| Example 15 | 28 | 10 |
| Example 16 | 26 | 10 |
| Example 17 | 28 | 11 |
| Example 18 | 28 | 12 |

[Evaluation of Resist Pattern by ArF Exposure]

### (Evaluation of Resist Patterning: Evaluation for Development Using Alkalithrough PTD Step)

The obtained organic underlayer film (A layer)-forming composition was applied to a silicon wafer, and baked at 240° C. for 60 seconds on a hot plate to obtain an organic underlayer film (A layer) having a film thickness of 200 nm. To the organic underlayer film, the Si-containing resist underlayer film (B layer)-forming composition obtained in each of Examples 1 to 18 and Comparative Examples 1 to 3 was applied, and baked at 240° C. for 60 seconds on a hot plate, to obtain an Si-containing resist underlayer film (B layer). The thickness of the Si-containing resist underlayer film (B layer) was 80 nm.

A commercially available resist solution for ArF (trade name: AR2772JN available from JSR Corporation) was applied to each of the B layers by a spinner, and heated at 110° C. for 1 minute on a hot plate to form a photoresist film (C layer) having a film thickness of 120 nm.

Each layered body was exposed by a scanner NSR-S307E manufactured by Nikon Corporation (wavelength: 193 nm, NA, σ: 0.85, 0.93/0.85) through a mask designed to form dense lines with a line width of 0.062 μm and a width between the lines of 0.062 μm, that was, a 0.062-μm line-and-space (L/S) of 1/1 in the photoresist after development. Each of the layered bodies was then baked at 100° C. for 60 seconds on a hot plate, cooled, and developed for 60 seconds by an alkali aqueous solution having a concentration of a 2.38% by mass, to form a positive pattern on the resist underlayer film (B layer). When large-scale peeling of the pattern, and increase in an undercut and a line bottom (footing) do not occur in the obtained photoresist pattern, the pattern profile is considered to be “good” in evaluation. When resist pattern collapse occurs in the obtained photoresist pattern, the pattern profile is considered to be “pattern collapse” in evaluation.

TABLE 5

| | Pattern profile |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Example 11 | Good |
| Example 12 | Good |
| Example 13 | Good |
| Example 14 | Good |
| Example 15 | Good |
| Example 16 | Good |
| Example 17 | Good |
| Example 18 | Good |
| Comparative Example 1 | Pattern collapse |
| Comparative Example 2 | Pattern collapse |
| Comparative Example 3 | Pattern collapse |

[Evaluation of Removability of Resist Underlayer Film by SPM Chemical Solution]

The resist underlayer film-forming composition prepared in each of Examples 1 to 18 and Comparative Example 1 was applied to a silicon wafer by a spinner. The resist underlayer film-forming composition was heated at 180° C. for 1 minute on a hot plate to form a resist underlayer film. RS-30 (mixed liquid of sulfuric acid with hydrogen peroxide: SPM chemical solution) available from Rasa Industries, Ltd., was applied to each of the resist underlayer films, rinsed with water, and dried by spinning. Changes in film thickness before and after applying the SPM chemical solution were evaluated. A case where the change in film thickness was 90% or more is considered to be “good.” A case where the change in film thickness is less than 90% is considered to be “not dissolved.” In the present invention, “not dissolved” means an unfavorable state.

TABLE 6
Evaluation of removability of resist underlayer
film by SPM chemical solution

| | |
|---|---|
| Example 1 | Good |
| Example 2 | Good |
| Example 3 | Good |
| Example 4 | Good |
| Example 5 | Good |
| Example 6 | Good |
| Example 7 | Good |
| Example 8 | Good |
| Example 9 | Good |
| Example 10 | Good |
| Example 11 | Good |
| Example 12 | Good |
| Example 13 | Good |
| Example 14 | Good |
| Example 15 | Good |
| Example 16 | Good |
| Example 17 | Good |
| Example 18 | Good |

### INDUSTRIAL APPLICABILITY

The present invention provides a silicon-containing resist underlayer film that is usable as a hard mask in a lithography process and can be removed by a wet process using a chemical solution, and particularly, a mixed aqueous solution of sulfuric acid with hydrogen peroxide (SPM).

1. A resist underlayer film-forming composition comprising a hydrolysis-condensate containing an organic group having a dihydroxy group, wherein the dihydroxy group in the hydrolysis-condensate containing an organic group having a dihydroxy group is produced by a ring opening reaction of an epoxy group in a hydrolysis-condensate containing an organic group having the epoxy group by an inorganic acid or a cation exchange resin, and the hydrolysis-condensate containing an organic group having an epoxy group is produced by hydrolysis-condensation of a hydrolysable silane having an epoxy group in an amount of 10 to 90% by mole relative to the total amount of hydrolysable silanes by an aqueous solution of an alkaline substance.

2. The resist underlayer film-forming composition according to claim 1, wherein the hydrolysable silane having an epoxy group in an amount of 10 to 90% by mole relative to the total amount of hydrolysable silanes contains a hydrolysable silane of Formula (1):
R¹ₐR²_{b}Si(R³)_{4-(a+b)} Formula (1)
(wherein R¹ is a cyclohexylepoxy group, a glycidoxyalkyl group, or an organic group containing a cyclohexylepoxy group and a glycidoxyalkyl group and bonded to a silicon atom through a Si—C bond, R² is an alkyl group, an aryl group, a halogenated alkyl group, a halogenated aryl group, an alkoxyaryl group, an alkenyl group, an acyloxyalkyl group, an organic group having an acryloyl group, a methacryloyl group, a mercapto group, an amino group, an amide group, a hydroxyl group, an alkoxy group, an ester group, a sulfonyl group, or a cyano group, or a combination thereof and bonded to a silicon atom through a Si—C bond, R³ is an alkoxy group, an acyloxy group, or a halogen group, a is an integer of 1, b is an integer of 0 to 2, and a+b is an integer of 1 to 3).

3. The resist underlayer film-forming composition according to claim 2, wherein the hydrolysable silane having an epoxy group in an amount of 10 to 90% by mole relative to the total amount of hydrolysable silanes contains the hydrolysable silane of Formula (1), and at least one selected from the group consisting of hydrolysable silanes of Formula (2):
R⁴_{c}Si(R⁵)_{4-c} Formula (2)
(wherein R⁴ is an alkyl group, an aryl group, a halogenated alkyl group, a halogenated aryl group, an alkoxyaryl group, an alkenyl group, an acyloxyalkyl group, an organic group having an acryloyl group, a methacryloyl group, a mercapto group, an amino group, an amide group, a hydroxyl group, an alkoxy group, an ester group, a sulfonyl group, or a cyano group, or a combination thereof and bonded to a silicon atom through a Si—C bond, R⁵ is an alkoxy group, an acyloxy group, or a halogen group, and c is an integer of 0 to 3), and Formula (3):
[R⁶_{d}Si(R⁷)_{3-d}]₂Yₑ Formula (3)
(wherein R⁶ is an alkyl group bonded to a silicon atom through an Si—C bond, R⁷ is an alkoxy group, an acyloxy group, or a halogen group, Y is an alkylene group or an arylene group, d is an integer of 0 or 1, and e is an integer of 0 or 1).

4. The resist underlayer film-forming composition according to claim 2, wherein the hydrolysable silane of Formula (1) is contained in an amount of 10 to 90% by mole relative to the total amount of hydrolysable silanes.

5. The resist underlayer film-forming composition according to claim 1, further comprising a crosslinkable compound.

6. The resist underlayer film-forming composition according to claim 1, further comprising an acid or an acid generator.

7. The resist underlayer film-forming composition according to claim 1, further comprising water.

8. The resist underlayer film-forming composition according to claim 1, wherein the production of hydrolysis-condensate by hydrolysis-condensation of the hydrolysable silane by the aqueous solution of an alkaline substance and the ring opening reaction of the epoxy group by the inorganic acid or the cation exchange resin occur in an organic solvent.

9. A resist underlayer film obtained by applying the resist underlayer film-forming composition according to claim 1 to a substrate and baking the composition, the resist underlayer film being capable of being removed by an aqueous solution containing sulfuric acid and hydrogen peroxide at a mass ratio of H₂SO₄:H₂O₂ of 1:1 to 4:1.

10. A method for producing the resist underlayer film-forming composition according to claim 1 comprising steps of:
producing a hydrolysis-condensate containing an organic group having an epoxy group by hydrolysis-condensation of a hydrolysable silane having an epoxy group in an amount of 10 to 90% by mole relative to the total amount of hydrolysable silanes by an aqueous solution of an alkaline substance; and
ring-opening the epoxy group in a reaction system containing the hydrolysis-condensate containing an organic group having the epoxy group by an inorganic acid or a cation exchange resin to obtain a hydrolysis-condensate containing an organic group having a dihydroxy group.

11. A method for producing a semiconductor device comprising steps of:
applying the resist underlayer film-forming composition according to claim 1 to a semiconductor substrate and baking the composition, to form a resist underlayer film;
applying a composition for a resist to the resist underlayer film to form a resist film;
exposing the resist film; after exposure, developing the resist to obtain a resist pattern;
etching the resist underlayer film through the resist pattern; and
processing the semiconductor substrate through the patterned resist and resist underlayer film.

12. A method for producing a semiconductor device comprising steps of:
forming an organic underlayer film on a semiconductor substrate;
applying the resist underlayer film-forming composition according to claim 1 to the organic underlayer film and baking the composition, to form a resist underlayer film;
applying a composition for a resist to the resist underlayer film to form a resist layer;
exposing the resist layer; after exposure, developing the resist to obtain a resist pattern;
etching the resist underlayer film through the resist pattern;
etching the organic underlayer film through the patterned resist underlayer film; and
processing the semiconductor substrate through the patterned organic underlayer film.

13. The method for producing a semiconductor device according to claim 11, further comprising a step of removing the patterned resist underlayer film by an aqueous solution containing sulfuric acid and hydrogen peroxide.
